(19) United States
(12) Patent Application Publication
(10) Pub. No.: US 2025/0127033 A1
(43) Pub. Date: Apr. 17, 2025

(54) LIGHT EMITTING ELEMENT, METHOD FOR MANUFACTURING THE LIGHT EMITTING ELEMENT, AND DISPLAY DEVICE COMPRISING THE LIGHT EMITTING ELEMENT

(71) Applicant: Samsung Display Co., Ltd., Yongin-si (KR)

(72) Inventors: Jungho JO, Yongin-si (KR); YUNKU JUNG, Yongin-si (KR); MYOUNGJIN PARK, Yongin-si (KR); YUNHYUK KO, Yongin-si (KR); DONGWOO SHIN, Yongin-si (KR)

(21) Appl. No.: 18/827,400

(22) Filed: Sep. 6, 2024

(30) Foreign Application Priority Data
Oct. 17, 2023 (KR) 10-2023-0138237

(51) Int. Cl. H10K 85/30; H10K 50/115; H10K 71/15

(52) U.S. Cl. CPC H10K 85/381; H10K 50/115; H10K 71/15

(57) ABSTRACT

A light emitting element may include a first electrode, an electron transport region on the first electrode and including metal nanoparticles, an emission layer on the electron transport region and including quantum dots, a hole transport region on the emission layer, and a second electrode disposed on the hole transport region. The metal nanoparticle may include a core including a metal oxide composed of zinc (Zn), magnesium (Mg), oxygen (O) and a first component, and a ligand bonded to the core and derived from an ionic compound represented by Formula 1. The first component may include sodium (Na) or lithium (Li). Accordingly, the light emitting element of an embodiment may show high efficiency and long lifetime.

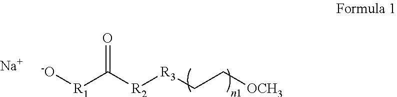

### CROSS-REFERENCE TO RELATED APPLICATIONS

The present application claims priority to and the benefit of Korean Patent Application No. 10-2023-0138237, filed on Oct. 17, 2023, the entire content of which is hereby incorporated by reference.

### BACKGROUND

Embodiments of the present disclosure described herein are related to a light emitting element including metal nanoparticles, a method for manufacturing the light emitting element, and a display device including the light emitting element.

A light emitting element is an element having conversion properties of electric energy into light energy. A quantum dot light emitting element including quantum dots in an emission layer in a light emitting element has relatively high color purity and relatively high emission efficiency and is possible to be polychromatic. In the light emitting element, holes move via a hole transport region to the emission layer, and electrons move via an electron transport region to the emission layer. Studies on smooth injection and transport of holes and electrons in a quantum dot light emitting element are being actively conducted or pursued for improving light efficiency.

### SUMMARY

Aspects according to one or more embodiments of the present disclosure are directed toward a light emitting element having relatively high efficiency and relatively long lifetime, and a display device including the same.

Aspects according to one or more embodiments of the present disclosure are directed toward a method for manufacturing a light emitting element having excellent or suitable manufacturing efficiency.

Additional aspects will be set forth in part in the description which follows and, in part, will be apparent from the description, or may be learned by practice of the presented embodiments of the disclosure.

According to one or more embodiments, a light emitting element may include: a first electrode; a second electrode arranged on the first electrode; and at least one functional layer arranged between the first electrode and the second electrode, wherein the at least one functional layer includes an emission layer including quantum dots and an electron transport region including metal nanoparticles, the metal nanoparticles include (e.g., each of the nanoparticles includes): a core including a metal oxide composed of zinc (Zn), magnesium (Mg), oxygen (O) and a first component; and a ligand bonded to the core and derived from an ionic compound represented by Formula 1, and the first component includes sodium (Na) or lithium (Li),

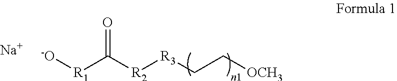

in Formula 1, R₁ is a direct linkage or an unsubstituted methylene group, R₂ and R₃ may each independently be a direct linkage, —O—*, or a substituted or unsubstituted methylene group, and n1 is an integer of 1 to 5.

According to one or more embodiments, the metal oxide may be represented by Formula M-1:

Znₓ₁Mg_{y1}Q_{z1}O Formula M-1
in Formula M-1, Q is Na or Li, a sum of x1, y1 and z1 is 1, x1 is a real number greater than 0 and at most 0.95, y1 is a real number greater than 0 and at most 0.3, and z1 is a real number greater than 0 and at most 0.3.

According to one or more embodiments, the ligand may include a first ligand including a Na⁺ ion of Formula 1 and a second ligand including an O— ion of Formula 1, and each of the first ligand and the second ligand may be bonded to a surface of the core (e.g., a surface of each of the cores of the metal nanoparticles).

According to one or more embodiments, the first ligand may be bonded to oxygen (O) at the surface.

According to one or more embodiments, the second ligand may be bonded to at least one selected from among zinc (Zn) and magnesium (Mg) at the surface.

According to one or more embodiments, the metal nanoparticle may have an absolute quantum efficiency of about 10% or less.

According to one or more embodiments, the content (e.g., amount) of an organic component present at a surface of the core may be about 15 wt % to about 25 wt % on the basis of about 100 wt % of the total weight of the metal nanoparticles.

According to one or more embodiments, the emission layer may be arranged between the electron transport region and the second electrode, and the at least one functional layer may further include a hole transport region arranged between the emission layer and the second electrode.

According to one or more embodiments, the emission layer may be arranged between the first electrode and the electron transport region, and the at least one functional layer may further include a hole transport region arranged between the first electrode and the emission layer.

According to one or more embodiments, the electron transport region may include an electron injection layer arranged on the first electrode, an electron transport layer arranged on the electron injection layer, and a hole blocking layer arranged on the electron transport layer, and at least one selected from among the electron injection layer, the electron transport layer, and the hole blocking layer may include the metal nanoparticles (e.g., the hole blocking layer may include the metal nanoparticles).

According to one or more embodiments a method for manufacturing a light emitting element may include: forming (e.g., providing or applying) a first electrode on a base layer; forming (e.g., providing or applying) at least one functional layer on the first electrode; and forming (e.g., providing or applying) a second electrode on the at least one functional layer, wherein the forming (or providing) of the at least one functional layer includes: providing quantum dots to form (or provide) an emission layer; and providing a composition including metal nanoparticles to form (or provide) an electron transport region, the metal nanoparticles include (e.g., each incudes): a core including a metal oxide composed of zinc (Zn), magnesium (Mg), oxygen (O) and a first component; and a ligand bonded to the core and derived from an ionic compound represented by Formula 1, and the first component includes sodium (Na) or lithium (Li).

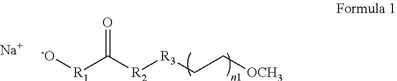

In Formula 1, R₁ is a direct linkage or an unsubstituted methylene group, R₂ and R₃ may each independently be a direct linkage, —O—*, or a substituted or unsubstituted methylene group, and n1 is an integer of 1 to 5.

According to one or more embodiments, the composition may be provided by an inkjet printing method or a dispensing method.

According to one or more embodiments, the composition may further include a first solvent in which the metal nanoparticles are dispersed, and the first solvent may include a material represented by Formula S-1.

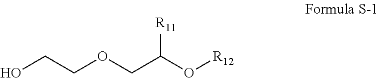

In Formula S-1, R₁₁ and R₁₂ may each independently be a hydrogen atom or a substituted or unsubstituted alkyl group of 1 to 10 carbon atoms, or combined with an adjacent group to form (or provide) a ring.

According to one or more embodiments, the composition may further include a first solvent in which the metal nanoparticles are dispersed, and the first solvent may include a material represented by at least one selected from among S-11 to S-18.

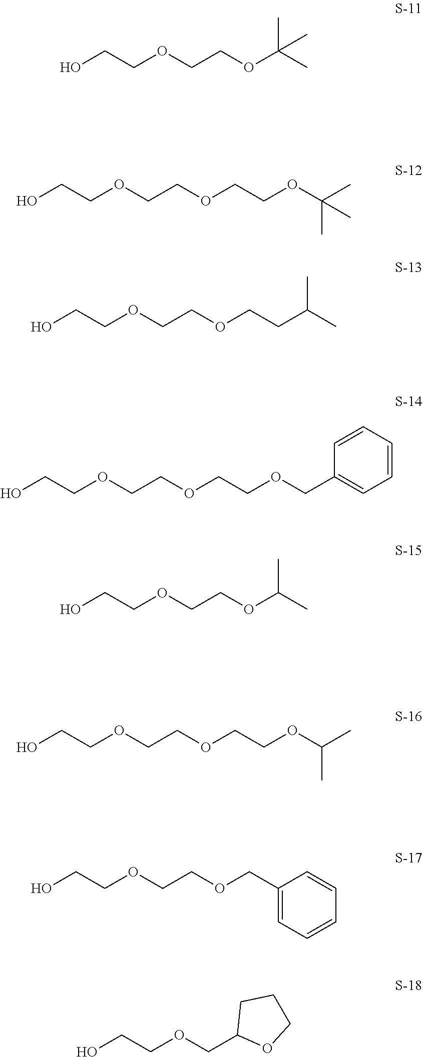

According to one or more embodiments, in the method for manufacturing a light emitting element, preparing the metal nanoparticles may be prior to the providing of the composition, and the preparing of the metal nanoparticles may include: preparing the core; and providing the core with the ionic compound to prepare the metal nanoparticles in which the ligand is bonded to a surface of the core (e.g., a surface of each of the cores of the metal nanoparticles).

According to one or more embodiments, the preparing of the core may include: preparing a mixture including a zinc precursor, a magnesium precursor, a first precursor and a second solvent; and providing the mixture with a third solvent including a hydroxyl group, and the first precursor may include a sodium precursor or a lithium precursor.

According to one or more embodiments, each of the zinc precursor, the magnesium precursor, and the first precursor may include an acetate ion or a halogen ion.

According to one or more embodiments, the second solvent may include at least one selected from among water (H₂O), ethylene glycol and dimethyl sulfoxide.

According to one or more embodiments, the third solvent may include at least one selected from among potassium hydroxide, sodium hydroxide, trimethylammonium hydroxide (TMAM), and tetramethylammonium hydroxide (TMAH).

According to one or more embodiments, the metal oxide may be represented by Formula M-1.

Znₓ₁Mg_{y1}Q_{z1}O Formula M-1

In Formula M-1, Q is Na or Li, a sum of x1, y1 and z1 is 1, x1 is a real number greater than 0 and at most 0.95, y1 is a real number greater than 0 and at most 0.3, and z1 is a real number greater than 0 and at most 0.3.

According to one or more embodiments, the ligand may include a first ligand including a Na⁺ ion of Formula 1 and a second ligand including an O— ion of Formula 1, and each of the first ligand and the second ligand may be bonded to a surface of the core (e.g., a surface of each of the cores of the metal nanoparticles).

According to one or more embodiments, the first ligand may be bonded to oxygen (O) at the surface, and the second ligand may be bonded to at least one selected from among zinc (Zn) and magnesium (Mg) at the surface.

According to one or more embodiments, the forming (or providing) of the emission layer may be performed after the forming (or providing) of the electron transport region, and the forming (or providing) of the at least one functional layer may further include forming (e.g., providing or applying) a hole transport region after the forming (or providing) of the emission layer.

According to one or more embodiments, the forming (or providing) of the emission layer may be performed prior to the forming (or providing) of the electron transport region, and the forming (or providing) of the at least one functional layer may further include forming (e.g., providing or applying) a hole transport region prior to the forming (or providing) of the emission layer.

According to one or more embodiments, a display device may include: a circuit layer; and a display element layer arranged on the circuit layer and including a pixel definition layer in which a pixel opening part is defined and a light emitting element, wherein the light emitting element includes: a first electrode exposed via the pixel opening part; a second electrode arranged on the first electrode; and at least one functional layer arranged between the first electrode and the second electrode, the at least one functional layer includes an emission layer including quantum dots and an electron transport region including metal nanoparticles, the metal nanoparticles include (e.g., each includes): a core including a metal oxide composed of zinc (Zn), magnesium (Mg), oxygen (O) and a first component; and a ligand bonded to the core and derived from an ionic compound represented by Formula 1, and the first component includes sodium (Na) or lithium (Li),

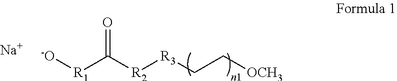

in Formula 1, R₁ is a direct linkage or an unsubstituted methylene group, R₂ and R₃ may each independently be a direct linkage, —O—*, or a substituted or unsubstituted methylene group, and n1 is an integer of 1 to 5.

According to one or more embodiments, the metal oxide may be represented by Formula M-1,

Znₓ₁Mg_{y1}Q_{z1}O Formula M-1
in Formula M-1, Q is Na or Li, a sum of x1, y1 and z1 is 1, x1 is a real number greater than 0 and at most 0.95, y1 is a real number greater than 0 and at most 0.3, and z1 is a real number greater than 0 and at most 0.3.

According to one or more embodiments, the ligand may include a first ligand including a Na⁺ ion of Formula 1 and a second ligand including an O⁻ ion of Formula 1, and each of the first ligand and the second ligand may be bonded to a surface of the core (e.g., a surface of each of the cores of the metal nanoparticles).

According to one or more embodiments, the first ligand may be bonded to oxygen (O) at the surface, and the second ligand may be bonded to at least one selected from among zinc (Zn) and magnesium (Mg) at the surface.

According to one or more embodiments, the emission layer may be arranged between the electron transport region and the second electrode, and the at least one functional layer may further include a hole transport region arranged between the emission layer and the second electrode.

According to one or more embodiments, the emission layer may be arranged between the first electrode and the electron transport region, and the at least one functional layer may further include a hole transport region arranged between the first electrode and the emission layer.

### BRIEF DESCRIPTION OF THE FIGURES

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a perspective view showing a display device according to one or more embodiments;

FIG. 2 is a cross-sectional view showing a part corresponding to line I-I′ in FIG. 1;

FIG. 3 is a plan view showing a display device according to one or more embodiments;

FIG. 4A is a cross-sectional view showing a part corresponding to line II-II′ in FIG. 3;

FIG. 4B is a cross-sectional view showing a display device according to one or more embodiments;

FIG. 5A is a cross-sectional view showing a light emitting element according to one or more embodiments;

FIG. 5B is a cross-sectional view showing a light emitting element according to one or more embodiments;

FIG. 5C is a cross-sectional view showing a light emitting element according to one or more embodiments;

FIG. 5D is a cross-sectional view showing a light emitting element according to one or more embodiments;

FIG. 6 is a diagram showing a metal nanoparticle according to one or more embodiments;

FIG. 7 is an enlarged diagram showing region XX′ in FIG. 6;

FIG. 8 is a graph evaluating and showing photoluminescence intensity for the Comparative Examples and the Example;

FIG. 9 is a flowchart showing a method for manufacturing a light emitting element according to one or more embodiments;

FIG. 10A is a flowchart showing a method for manufacturing a light emitting element according to one or more embodiments;

FIG. 10B is a flowchart showing a method for manufacturing a light emitting element according to one or more embodiments;

FIG. 11 is a diagram schematically showing a manufacturing operation of a light emitting element according to one or more embodiments;

FIG. 12A is a diagram schematically showing a manufacturing operation of a light emitting element according to one or more embodiments;

FIG. 12B is a diagram schematically showing a manufacturing operation of a light emitting element according to one or more embodiments; and

FIG. 13 is an enlarged diagram showing region AA′ in FIG. 12A.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

In the description, when an element (or a region, a layer, a part, and/or the like) is referred to as being “on”, “connected with” or “combined with” another element, it can be directly arranged on/connected with/bonded to the other element, or intervening third elements may also be arranged.

Like reference numerals refer to like elements throughout, and duplicative descriptions thereof may not be provided. In the drawings, the thicknesses, ratios, and dimensions of elements are exaggerated for effective explanation of technical contents. As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

As used herein, the singular forms “a,” “an” and “the” are intended to include the plural forms as well, unless the context clearly indicates otherwise.

In present disclosure, “not including a or any ‘component”’ “excluding a or any ‘component”’, “‘component’-free”, and/or the like refers to that the “component” not being added, selected or utilized as a component in the composition/structure, but the “component” of less than a suitable amount may still be included due to other impurities and/or external factors.

Here, unless otherwise defined, the listing of operations, tasks, or acts in a particular order should not necessarily means that the invention or claims require that particular order. That is, the general rule that unless the operations, tasks, or acts of a method (e.g., a method claim) actually recite an order, the operations, tasks, or acts should not be construed to require one.

In the present disclosure, when dot, dots, particle, or particles are spherical, “size” or “diameter” indicates a particle diameter or an average particle diameter, and when they are non-spherical, the “size” or “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

It will be understood that, although the terms first, second, and/or the like may be utilized herein to describe one or more suitable elements, these elements should not be limited by these terms. These terms are only utilized to distinguish one element from another element. For example, a first element could be termed a second element without departing from the scope of the present disclosure. Similarly, a second element could be termed a first element. As utilized herein, the singular forms are intended to include the plural forms as well, unless the context clearly indicates otherwise.

In one or more embodiments, the terms “below”, “beneath”, “on” and “above” are utilized for explaining the relation of elements shown in the drawings. The terms are relative concept and are explained based on the direction shown in the drawing.

It will be further understood that the terms “comprises” or “comprising,” when utilized in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) utilized herein have the same meaning as commonly understood by one of ordinary skill in the art to which this present disclosure belongs. In one or more embodiments, it will be further understood that terms, such as those defined in commonly utilized dictionaries, should be interpreted as having a meaning that is consistent with their meaning in the context of the relevant art and will not be interpreted in an idealized or overly formal sense unless expressly defined so herein.

In the description, the term “substituted or unsubstituted” corresponds to substituted or unsubstituted with at least one substituent of (e.g., selected from among) the group including (e.g., consisting of) a deuterium atom, a halogen atom, a hydroxyl group, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the example substituents may be substituted or unsubstituted. For example, a biphenyl group may be interpreted as an aryl group or a phenyl group substituted with a phenyl group.

In the description, the term “forming a ring via the combination with an adjacent group” may refer to forming (or providing) a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In one or more embodiments, the ring formed via the combination with an adjacent group may be combined with another ring to form (or provide) a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In one or more embodiments, in 4,5-dimethylphenanthrene, two methyl groups may be interpreted as “adjacent groups” to each other.

In the description, examples of a halogen atom may include a fluorine atom, a chlorine atom, a bromine atom or an iodine atom.

In the description, an alkyl group may be a linear, or branched type or kind. The carbon number of the alkyl group may be 1 to 60, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, and/or the like, without limitation.

In the description, the same explanation on the alkyl group may be applied to an alkylene group except that the alkylene group is a divalent group.

In the description, an aryl group refers to an optional functional group or substituent derived from an aromatic hydrocarbon ring. The aryl group may be a monocyclic aryl group or a polycyclic aryl group. The carbon number for forming (or providing) rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, and/or the like, without limitation.

In the description, an oxy group may refer to the above-defined alkyl group or aryl group which is combined with an oxygen atom. The oxy group may include an alkoxy group and an aryl oxy group. The aryl group in the aryl oxy group may be the same as the examples of the aryl group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like. However, an embodiment of the present disclosure is not limited thereto.

In the description, a direct linkage may refer to a single bond. In the description,

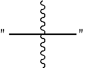

and “—*” refer to positions to be connected.

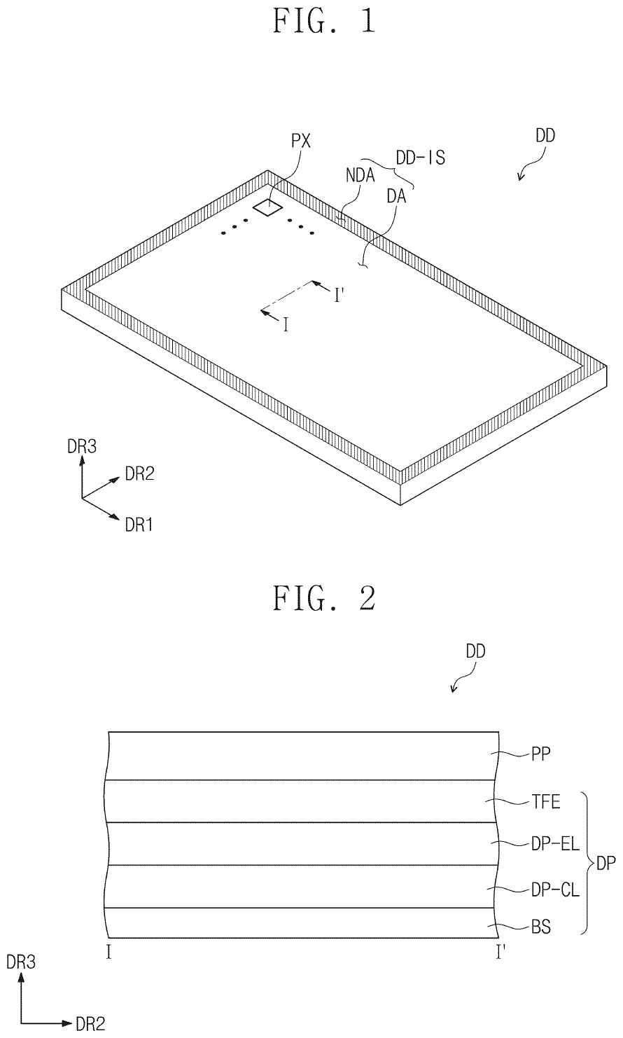

Hereinafter, a light emitting element according to one or more embodiments of the present disclosure and a display device including the light emitting element will be explained referring to the drawings. FIG. 1 is a perspective view showing a display device of an embodiment.

Referring to FIG. 1, the display device DD according to one or more embodiments may be a device activated by electrical signals. For example, the display device DD may be a large-sized device such as a television, a monitor and an external billboard. In one or more embodiments, the display device DD may be small- and medium-sized devices such as a personal computer, a laptop computer, a personal digital terminal, a car navigation unit, a game console, a smart phone, a tablet and a camera. In one or more embodiments, these are suggested only as examples, and the display device DD may be employed as other display devices unless deviated from the present disclosure.

The display device DD may display images (or videos) through a display surface DD-IS. The display surface DD-IS may be parallel to a plane defined by a first directional axis DR1 and a second directional axis DR2. The display surface DD-IS may include a display area DA and a non-display area NDA.

In the display area DA, a pixel PX may be arranged, and in the non-display area NDA, the pixel PX may not be arranged. The non-display area NDA may be defined along the edge of the display surface DD-IS. The non-display area NDA may surround the display area DA. However, one or more embodiments of the present disclosure is not limited thereto, and the non-display area NDA may not be provided, or the non-display area NDA may be arranged only at one side of the display area DA.

In FIG. 1, a display device DD provided with a planar display surface DD-IS is shown, but one or more embodiments of the present disclosure is not limited thereto. The display device DD may include a curve-type or kind display surface or a three-dimensional display surface. The three-dimensional display surface may include multiple display areas indicating other directions from each other.

In FIG. 1 and the drawings herein, a first directional axis DR1 to a third directional axis DR3 are shown, and the directions indicated by the first to third directional axes DR1, DR2 and DR3, explained in the description have a relative concept and may be converted to other directions. In one or more embodiments, the directions indicated by the first to third directional axes DR1, DR2 and DR3 may be explained as first to third directions, and the same reference symbols may be utilized. In the description, the first directional axis DR1 and the second directional axis DR2 may be orthogonal to each other, and the third directional axis DR3 may be the normal direction to a plane defined by the first directional axis DR1 and the second directional axis DR2.

In the description, a plane refers to a plane defined by the first directional axis DR1 and the second directional axis DR2, a cross-section may refer to a surface normal (e.g., perpendicular) to the plane defined by the first directional axis DR1 and the second directional axis DR2 and parallel to the third directional axis DR3. The thickness direction of the display device DD may be a direction parallel to the third direction DR3 that is a normal direction to the plane defined by the first direction DR1 and the second direction DR2.

In the description, the top surface (or front surface) and bottom surface (or rear surface) of the members constituting the display device DD may be defined based on the third direction DR3. More particularly, for one element, a surface relatively adjacent to the display surface DD-IS among two facing surfaces based on the third direction DR3 may be defined as the front surface (or top surface), and a surface relatively separated apart from the display surface DD-IS may be defined as the rear surface (or bottom surface). In one or more embodiments, in the description, an upper part (or upper side) or a lower part (or lower side) may be defined based on the third direction DR3, and the upper part (or upper side) may be defined as a direction close to the display surface DD-IS, and the lower part (lower side) may be defined as a direction away from the display surface DD-IS.

In the description, one element is “disposed directly/formed directly on” another element, may refer to that there are no third elements between the one element and another element. For example, one element is “disposed directly/formed directly on” another element, may refer to that the one element and another element make “contact” from each other.

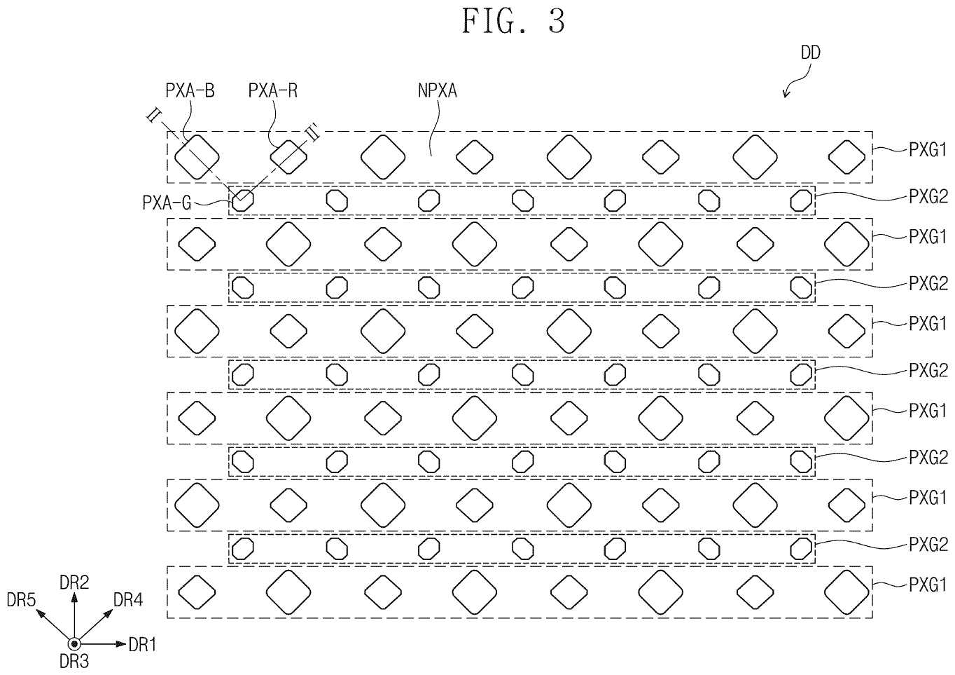

FIG. 2 is a cross-sectional view showing a part corresponding to line I-I′. FIG. 2 may be the cross-sectional view of a display device according to one or more embodiments.

The display device DD may include a display panel DP and an optical layer PP arranged on the display panel DP. The display panel DP may include a base layer BS, a circuit layer DP-CL arranged on the base layer BS, a display element layer DP-EL arranged on the circuit layer DP-CL, and an encapsulating layer TFE arranged on the display element layer DP-EL.

The display panel DP may be an element substantially producing images. The display panel DP may be an emission-type or kind display panel. For example, the display panel DP may be a quantum dot emission display panel including a quantum dot light emitting element.

The base layer BS may be a member providing a base surface for disposing the circuit layer DP-CL. The base layer BS may be a rigid substrate or a flexible substrate of which bending, folding, rolling, and/or the like is possible. The base layer BS may be a glass substrate, a metal substrate or a polymer substrate. However, one or more embodiments of the present disclosure is not limited thereto, and the base layer BS may be an inorganic layer, an organic layer or a composite material layer.

The circuit layer DP-CL may be arranged on the base layer BS. The circuit layer DP-CL may include an insulating layer, a semiconductor pattern, a conductive pattern, and a signal line. After forming (or providing) an insulating layer, a semiconductor layer and a conductive layer on the base layer BS by a method of coating, depositing, and/or the like, the insulating layer, semiconductor layer and conductive layer may be selectively patterned through multiple photolithography processes. After that, a semiconductor pattern, a conductive pattern, and a signal line, included in the circuit layer DP-CL may be formed.

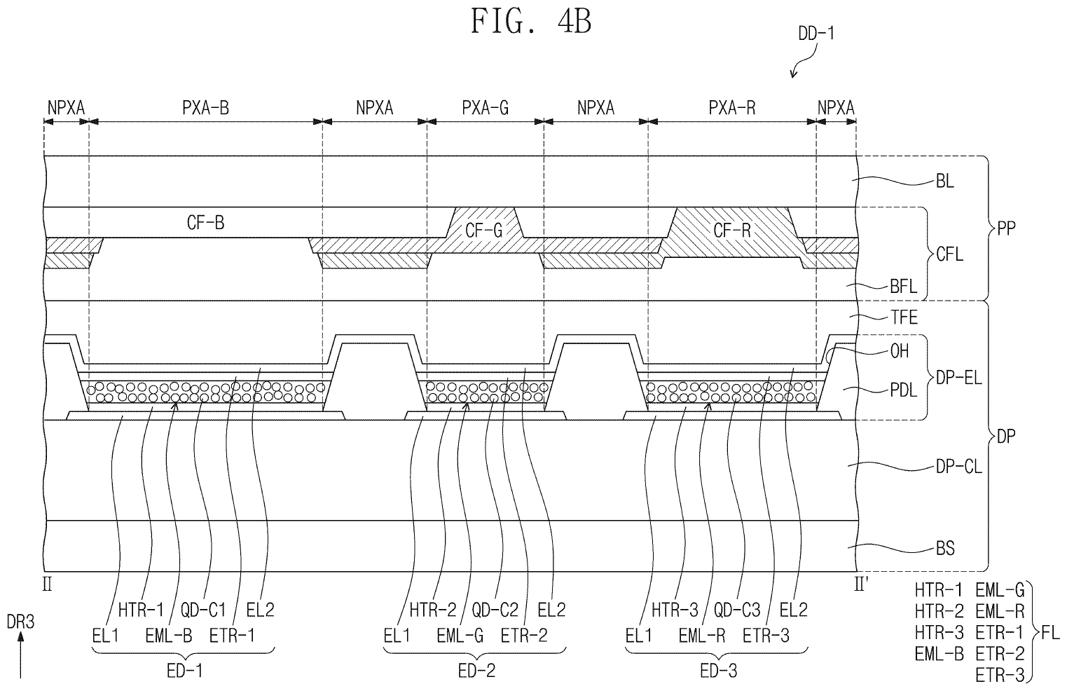

The display element layer DP-EL may be arranged on the circuit layer DP-CL. The display element layer DP-EL may include a pixel definition layer PDL (FIG. 4A and FIG. 4B), and first to third light emitting elements ED-1, ED-2 and ED-3 (FIG. 4A and FIG. 4B), which will be explained in more detail later. For example, the display element layer DP-EL may include an organic light emitting material, an inorganic light emitting material, an organic-inorganic light emitting material, a quantum dot, a quantum rod, a micro LED, or a nano LED. More particularly, the display element layer DP-EL may include a quantum dot.

The encapsulating layer TFE may protect the display element layer DP-EL from foreign materials such as moisture, oxygen and dust particles. The encapsulating layer TFE may include at least one inorganic layer. The encapsulating layer may include a stacked structure of an inorganic layer, an organic layer and an inorganic layer in order.

The optical layer PP may be arranged on the display panel DP and may control reflected light at the display panel DP by external light. The optical layer PP may include, for example, a polarization layer or a color filter layer. In one or more embodiments, different from the drawings, the optical layer PP may not be provided.

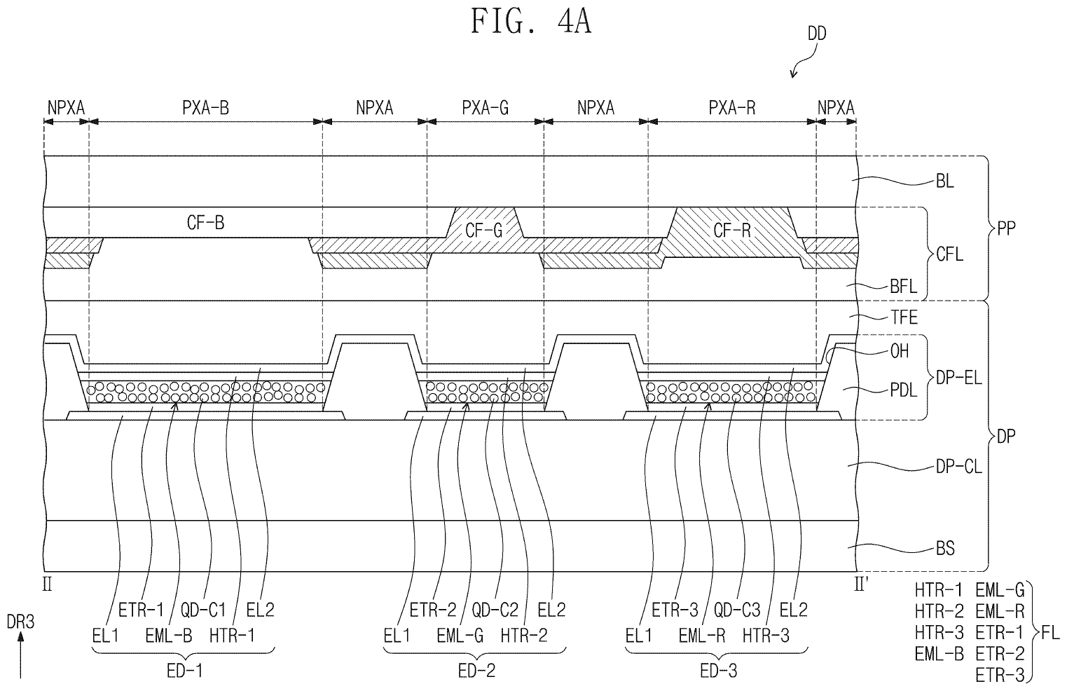

FIG. 3 is a plan view showing a display device DD according to one or more embodiments. FIG. 4A is a cross-sectional view showing a part corresponding to line II-II′ in FIG. 3. FIG. 3 may be a plan view showing a display are DA (FIG. 1) of a display device DD. FIG. 4A may be a cross-sectional view showing a display device DD according to one or more embodiments.

Referring to FIG. 3 and FIG. 4A, a display device DD may include a peripheral area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The areas of the luminous areas PXA-R, PXA-G and PXA-B may different from each other, and in this case, the area may refer to an area on a plane.

The luminous areas PXA-R, PXA-G and PXA-B may be divided into multiple groups according to the color of light produced from the light emitting elements ED-1, ED-2 and ED-3. In FIG. 3 and FIG. 4A, three luminous areas PXA-R, PXA-G and PXA-B configured to emit red light, green light and blue light are illustrated according to one or more embodiments. For example, the display device DD according to one or more embodiments may include a red luminous area PXA-R, a green luminous area PXA-G and a blue luminous area PXA-B, which are divided from each other.

The display panel DP may include multiple light emitting elements ED-1, ED-2 and ED-3 configured to emit light having different wavelength regions from each other. The multiple light emitting elements ED-1, ED-2 and ED-3 may be configured to emit light of different colors from each other. For example, the display panel DP may include a first light emitting element ED-1 configured to emit blue light, a second light emitting element ED-2 configured to emit green light, and a third light emitting element ED-3 configured to emit red light. However, one or more embodiments of the present disclosure is not limited thereto, and the first to third light emitting elements ED-1, ED-2 and ED-3 may be configured to emit light in substantially the same wavelength region, or at least one thereof may be configured to emit light in a different wavelength region.

In the display device DD of an embodiment, shown in FIG. 3 and FIG. 4A, the luminous areas PXA-R, PXA-G and PXA-B may have different areas according to the color emitted from the emission layers EML-B, EML-G and EML-R of the light emitting elements ED-1, ED-2 and ED-3. The blue luminous area PXA-B of the first light emitting element ED-1, configured to emit blue light may have the largest area, the green luminous area PXA-G of the second light emitting element ED-2, configured to emit green light may have the smallest area. However, one or more embodiments of the present disclosure is not limited thereto, and the luminous areas PXA-R, PXA-G and PXA-B may be configured to emit light of a color different from red light, green light and blue light. In one or more embodiments, the luminous areas PXA-R, PXA-G and PXA-B may have the same area, or the luminous areas PXA-R, PXA-G and PXA-B may be provided with an area ratio different from that shown in FIG. 3.

Each of the luminous areas PXA-R, PXA-G and PXA-B may be an area divided or defined by a pixel definition layer PDL. The peripheral areas NPXA may be areas between neighboring luminous areas PXA-R, PXA-G and PXA-B and may be an area corresponding to the pixel definition layer PDL. Each of the luminous areas PXA-R, PXA-G and PXA-B may correspond to a pixel.

The pixel definition layer PDL may define the luminous areas PXA-R, PXA-G and PXA-B. The luminous areas PXA-R, PXA-G and PXA-B and the peripheral area NPXA may be divided by the pixel definition layer PDL.

The blue luminous areas PXA-B and the red luminous areas PXA-R may be arranged by turns along a first directional axis DR1 to form (or provide) a first group PXG1. The green luminous areas PXA-G may be arranged along the first directional axis DR1 to form (or provide) a second group PXG2. The first group PXG1 may be separately arranged in the second directional axis DR2 with respect to the second group PXG2. Multiple first groups PXG1 and multiple second groups PXG2 may be provided. The first groups PXG1 and the second groups PXG2 may be arranged by turns in the second directional axis DR2.

One red luminous area PXA-R may be separately arranged in a fourth directional axis DR4 from one green luminous area PXA-G. One blue luminous area PXA-B may be separately arranged in a fifth directional axis DR5 from one green luminous area PXA-G. The fourth directional axis DR4 may be a direction between the first directional axis DR1 and the second directional axis DR2. The fifth directional axis DR5 may be a direction crossing the fourth directional axis DR4 and tilted with respect to the second directional axis DR2.

In one or more embodiments, the arrangement structure of the luminous areas PXA-R, PXA-G and PXA-B is not limited to the arrangement structure shown in FIG. 3. For example, in the luminous areas PXA-R, PXA-G and PXA-B, the red luminous area PXA-R, the green luminous area PXA-G and the blue luminous area PXA-B may be arranged by turns along the first directional axis DR1. In one or more embodiments, on a plane, the shapes of the luminous areas PXA-R, PXA-G and PXA-B are not limited to those shown in the drawing, and may be defined into shapes different from those shown in the drawing.

In FIG. 4A, the base layer BS may include a single layer or a multiplayer structure. For example, the base layer BS may include a first synthetic resin layer, an interlayer of a multilayer or a single layer structure, and a second synthetic resin layer. The interlayer may be referred to as a base barrier layer. The interlayer may include a silicon oxide (SiOₓ) layer and an amorphous silicon (a-Si) layer arranged on the silicon oxide layer, but one or more embodiments of the present disclosure is not specifically limited thereto. For example, the interlayer may include at least one selected from among a silicon oxide layer, a silicon nitride layer, a silicon oxynitride layer, and an amorphous silicon layer.

Each of the first and second synthetic resin layers may include a polyimide-based resin. In one or more embodiments, each of the first and second synthetic resin layers may include at least one selected from among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. In the description, “˜˜”-based resin refers to a resin including the functional group of “˜˜”.

The circuit layer DP-CL may be arranged on the base layer BS, and the circuit layer DP-CL may include multiple transistors. Each of the transistors may include a control electrode, an input electrode, and an output electrode. For example, the circuit layer DP-CL may include a switching transistor and a driving transistor for driving the light emitting elements ED-1, ED-2 and ED-3 of the display element layer DP-EL.

The display element layer DP-EL may include the pixel definition layer PDL and the first to third light emitting elements ED-1, ED-2 and ED-3. In the pixel definition layer PDL, a pixel opening part OH may be defined. The pixel definition layer PDL may divide the first to third light emitting elements ED-1, ED-2 and ED-3. The emission layers EML-B, EML-G and EML-R of the first to third light emitting elements ED-1, ED-2 and ED-3 may be arranged and divided in the pixel opening part OH defined in the pixel definition layer PDL.

The pixel definition layer PDL may be formed utilizing a polymer resin. For example, the pixel definition layer PDL may be formed by including a polyacrylate-based resin or a polyimide-based resin. In one or more embodiments, the pixel definition layer PDL may be formed by further including an inorganic material in addition to the polymer resin. In one or more embodiments, the pixel definition layer PDL may be formed by including a light absorption material or formed by including a black pigment or a black dye. The pixel definition layer PDL formed by including a black pigment or a black dye may accomplish a black pixel definition layer. Carbon black, and/or the like may be utilized as the black pigment or the black dye during forming (or providing) the pixel definition layer PDL, but one or more embodiments of the present disclosure is not limited thereto.

In one or more embodiments, the pixel definition layer PDL may be formed utilizing an inorganic material. For example, the pixel definition layer PDL may be formed utilizing an inorganic material including silicon nitride (SiNₓ), silicon oxide (SiOₓ), silicon oxynitride (SiOₓN_{y}), and/or the like. x and y may each be a real number suitable in the art.

Each of the light emitting elements ED-1, ED-2 and ED-3 may include a first electrode EL1, a second electrode EL2 arranged on the first electrode EL1, and at least one functional layer FL arranged between the first electrode EL1 and the second electrode EL2. The at least one functional layer FL may include electron transport regions ETR-1, ETR-2 and ETR-3 and emission layers EML-B, EML-G and EML-R. In one or more embodiments, the at least one functional layer FL may further include hole transport regions HTR-1, HTR-2 and HTR-3.

Referring to FIG. 4A, each of the light emitting elements ED-1, ED-2 and ED-3 may include a first electrode EL1, electron transport regions ETR-1, ETR-2 and ETR-3 arranged on the first electrode EL1, emission layers EML-B, EML-G and EML-R arranged on the electron transport regions ETR-1, ETR-2 and ETR-3, hole transport regions HTR-1, HTR-2 and HTR-3 arranged on the emission layers EML-B, EML-G and EML-R, and a second electrode arranged on the hole transport regions HTR-1, HTR-2 and HTR-3. The emission layers EML-B, EML-G and EML-R may be arranged between the electron transport regions ETR-1, ETR-2 and ETR-3 and the second electrode EL2, and the hole transport regions HTR-1, HTR-2 and HTR-3 may be arranged between the emission layers EML-B, EML-G and EML-R and the second electrode EL2.

At least a portion of the first electrode EL1 may be exposed at the pixel opening part OH of the pixel definition layer PDL. The first electrode EL1 may have conductivity. The first electrode EL1 may be formed utilizing a metal material, a metal alloy or a conductive compound. The first electrode EL1 may be a cathode or an anode. However, an embodiment of the present disclosure is not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, or oxides thereof.

If the first electrode EL1 is the transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure including multiple layers including a reflective layer or a transflective layer formed utilizing the above materials, and a transmissive conductive layer formed utilizing ITO, IZO, ZnO, or ITZO. For example, the first electrode EL1 may have a three-layer structure of ITO/Ag/ITO, without limitation. In one or more embodiments, the first electrode EL1 may include the above-described metal materials, combinations of two or more metal materials selected from among the above-described metal materials, or oxides of the above-described metal materials. However, one or more embodiments of the present disclosure is not limited thereto. The thickness of the first electrode EL1 may be from about 700 angstrom (A) to about 10,000 Å. For example, the thickness of the first electrode EL1 may be from about 1,000 Å to about 3,000 Å.

The second electrode EL2 may be a common electrode. The second electrode EL2 may be an anode or a cathode, but one or more embodiments of the present disclosure is not limited thereto. For example, if the first electrode EL1 is an anode, the second electrode EL2 may be a cathode, and if the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, compound(s) of two or more selected therefrom, mixture(s) of two or more selected therefrom, or oxide(s) thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, and/or the like.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, compounds including thereof, or mixtures thereof (for example, AgMg, AgYb, or MgYb). In one or more embodiments, the second electrode EL2 may have a multilayered structure including a reflective layer or a transflective layer formed utilizing the above-described materials and a transparent conductive layer formed utilizing ITO, IZO, ZnO, ITZO, and/or the like For example, the second electrode EL2 may include the aforementioned metal materials, combinations of two or more metal materials selected from among the aforementioned metal materials, or oxides of the aforementioned metal materials.

In one or more embodiments, the second electrode EL2 may be connected with an auxiliary electrode. If the second electrode EL2 is connected with the auxiliary electrode, the resistance of the second electrode EL2 may decrease.

Between the first electrode EL1 and the second electrode EL2, emission layers EML-B, EML-G and EML-R may be arranged. The first light emitting element ED-1 may include the first emission layer EML-B, the second light emitting element ED-2 may include the second emission layer EML-G, and the third light emitting element ED-3 may include the third emission layer EML-R. The first emission layer EML-B may include a first quantum dot QD-C1. The second emission layer EML-G may include a second quantum dot QD-C2. The third emission layer EML-R may include the third quantum dot QD-C3.

The quantum dots QD-C1, QD-C2 and QD-C3 included in the emission layers EML-B, EML-G and EML-R may be stacked to form (or provide) layers. In FIG. 4A, quantum dots QD-C1, QD-C2 and QD-C3 having a circular shape cross-sections are arranged to form (or provide) roughly two layers according to one or more embodiments, but one or more embodiments of the present disclosure is not limited thereto. For example, according to the thicknesses of the emission layers EML-B, EML-G and EML-R, the shapes of the quantum dots QD-C1, QD-C2 and QD-C3 included in the emission layers EML-B, EML-G and EML-R, and the average diameters of the quantum dots QD-C1, QD-C2 and QD-C3, the arrangement of the quantum dots QD-C1, QD-C2 and QD-C3 may be changed. For example, the quantum dots QD-C1, QD-C2 and QD-C3 in the emission layers EML-B, EML-G and EML-R may be arranged in the neighborhood to form (or provide) one layer, or arranged to form (or provide) a multilayer of two layers, three layers, and/or the like.

The first quantum dot QD-C1 of the first light emitting element ED-1 may be configured to emit blue light. The second quantum dot QD-C2 of the second light emitting element ED-2 may be configured to emit green light. The third quantum dot QD-C3 of the third light emitting element ED-3 may be configured to emit red light. Each of the quantum dots QD-C1, QD-C2 and QD-C3 may include a core and a shell around (e.g., surrounding) the core. Accordingly, each of the quantum dots QD-C1, QD-C2 and QD-C3 may include a core-shell structure. The cores of the quantum dots QD-C1, QD-C2 and QD-C3 may include different materials from each other. Differently, the cores of the quantum dots QD-C1, QD-C2 and QD-C3 may include the same material. In one or more embodiments, two cores among the cores of the quantum dots QD-C1, QD-C2 and QD-C3 may include the same material, and the remaining one core may include a different material.

In FIG. 4A, the diameters of the first to third quantum dots QD-C1, QD-C2 and QD-C3 are shown similar, but an embodiment of the present disclosure is not limited thereto. The diameters of the first to third quantum dots QD-C1, QD-C2 and QD-C3 may be different from each other. For example, the first quantum dot QD-C1 of the first light emitting element ED-1, emitting light of a relatively short wavelength region may have a relatively smaller average diameter when compared to the second quantum dot QD-C2 of the second light emitting element ED-2 and the third quantum dot QD-C3 of the third light emitting element ED-3. The average diameter refers to an arithmetic average value of the particle diameters of multiple quantum dots. The particle diameter of the quantum dots may be an average value of the widths on the cross-sections of the quantum dot particles.

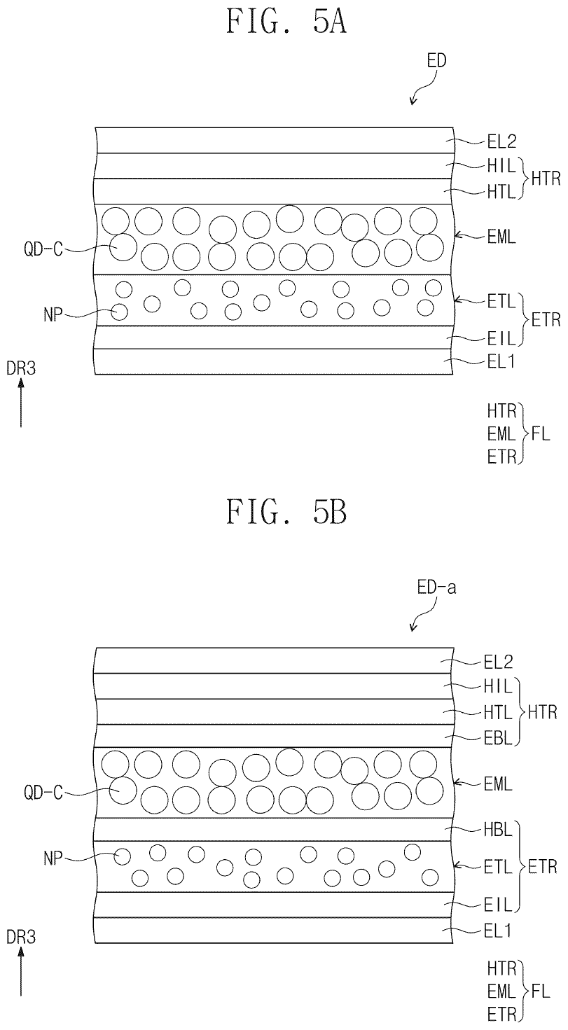

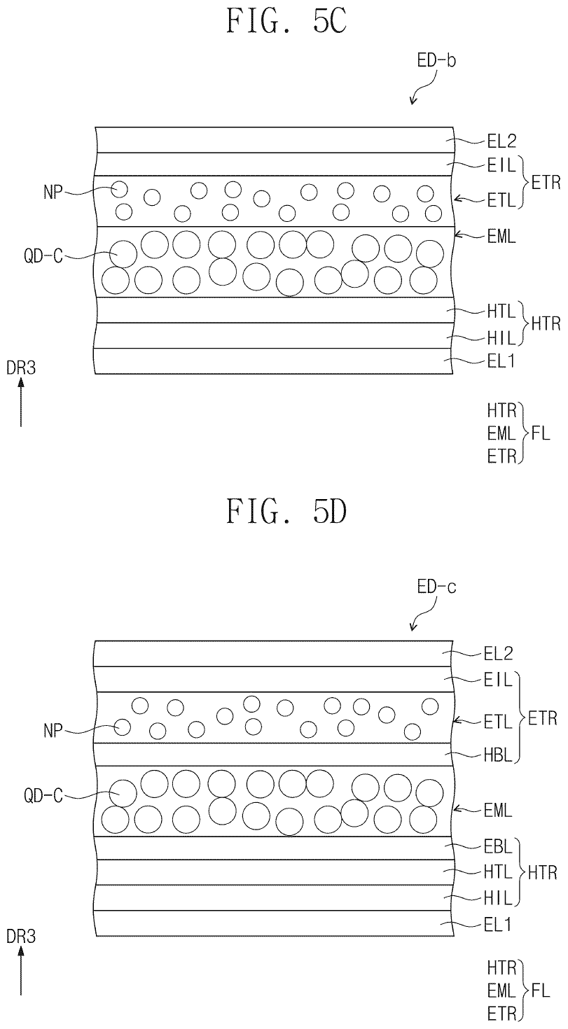

Between the first electrode EL1 and the emission layers EML-B, EML-G and EML-R, the electron transport regions ETR-1, ETR-2 and ETR-3 may be arranged. In one or more embodiments, the electron transport regions ETR-1, ETR-2 and ETR-3 may include metal nanoparticles NP (FIG. 5A to FIG. 5D). In one or more embodiments, the metal nanoparticle NP (FIG. 5A to FIG. 5D) may include a core MC (FIG. 6) and a ligand LD (FIG. 6) bonded to the core MC (FIG. 6). The core (FIG. 6) may include a metal oxide composed of four components including sodium (Na) or lithium (Li), and the ligand LD (FIG. 6) may be derived from an ionic compound including a Na⁺ ion and a glycolate ion moiety. The metal nanoparticle NP (FIG. 5A to FIG. 5D) including the core MC (FIG. 6) including sodium or lithium and the ligand LD (FIG. 6) derived from the Na⁺ ion and the glycolate ion moiety may show excellent or suitable dispersibility, stability over time and discharge stability, and may improve the light efficiency and the lifetime of the light emitting elements ED-1, ED-2 and ED-3. The metal nanoparticle NP (FIG. 5A to FIG. 5D) will be explained in more detail later.

The electron transport regions ETR-1, ETR-2 and ETR-3 of the first to third light emitting elements ED-1, ED-2 and ED-3 may be arranged and divided in the pixel opening part OH. The first light emitting element ED-1 may include the first electron transport region ETR-1, the second light emitting element ED-2 may include the second electron transport region ETR-2, and the third light emitting element ED-3 may include the third electron transport region ETR-3.

Each of the first to third electron transport regions ETR-1, ETR-2 and ETR-3 may have a single layer formed utilizing a single material, a single layer formed utilizing multiple different materials, or a multilayer structure having multiple layers formed utilizing different materials. The thicknesses of the first to third electron transport regions ETR-1, ETR-2 and ETR-3 may be, for example, about 1000 Å to about 1500 Å.

The first to third electron transport regions ETR-1, ETR-2 and ETR-3 may further include a suitable electron injection material and/or a suitable electron transport material. For example, the first to third electron transport regions ETR-1, ETR-2 and ETR-3 may include an anthracene-based compound. In one or more embodiments, the first to third electron transport regions ETR-1, ETR-2 and ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalen-2-yl)anthracene (ADN), 1,3-bis[3,5-di(pyridin-3-yl)phenyl]benzene (BmPyPhB), and mixtures thereof. In one or more embodiments, the first to third electron transport regions ETR-1, ETR-2 and ETR-3 may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

Between the emission layers EML-B, EML-G and EML-R and the second electrode EL2, the hole transport regions HTR-1, HTR-2 and HTR-3 may be arranged. The hole transport regions HTR-1, HTR-2 and HTR-3 of the first to third light emitting elements ED-1, ED-2 and ED-3 may be arranged in the pixel opening part OH to be divided. The first light emitting element ED-1 may include the first hole transport region HTR-1, the second light emitting element ED-2 may include the second hole transport region HTR-2, and the third light emitting element ED-3 may include the third hole transport region HTR-3.

Each of the hole transport regions HTR-1, HTR-2 and HTR-3 may have a single layer formed utilizing a single material, a single layer formed utilizing multiple different materials, or a multilayer structure including multiple layers formed utilizing multiple different materials. The thicknesses of the first to third hole transport regions HTR-1, HTR-2 and HTR-3 may be, for example, about 50 Å to about 15,000 Å. The thicknesses of the first to third hole transport regions HTR-1, HTR-2 and HTR-3 may be, for example, about 100 Å to about 10,000 Å, for example, about 100 Å to about 5,000 Å.

The first to third hole transport regions HTR-1, HTR-2 and HTR-3 may include a suitable hole injection material and/or a suitable hole transport material. For example, the first to third hole transport regions HTR-1, HTR-2 and HTR-3 may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HATCN).

In one or more embodiments, the first to third hole transport regions HTR-1, HTR-2 and HTR-3 may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(naphthalene-l-yl)-N,N′-diplienyl-benzidine (NPB), 4,4′-cyclohexylidene bis[N,N-bis(4-methylphenyl)benzeneamine](TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), or 1,3-bis(1,8-dimethyl-9H-carbazol-9-yl)benzene (mDCP), and/or the like.

The encapsulating layer TFE may include at least one inorganic layer (hereinafter, encapsulating inorganic layer). In one or more embodiments, the encapsulating layer TFE may include at least one organic layer (hereinafter, encapsulating organic layer) and at least one encapsulating inorganic layer.

The encapsulating inorganic layer may protect the display element layer DP-EL from moisture/oxygen, and the encapsulating organic layer may protect the display element layer DP-EL from foreign materials such as dust particles. The encapsulating inorganic layer may include silicon nitride, silicon oxynitride, silicon oxide, titanium oxide, or aluminum oxide, without specific limitation. The encapsulating organic layer may include an acrylic compound, an epoxy-based compound, and/or the like. The encapsulating organic layer may include a photopolymerizable organic material, without specific limitation.

An optical layer PP may include a base substrate BL and a color filter layer CFL. The base substrate BL may be a member providing a base surface where the color filter layer CFL is arranged. The base substrate BL may be a glass substrate, a metal substrate, a plastic substrate, and/or the like. However, one or more embodiments of the present disclosure is not limited thereto, but the base substrate BL may be an inorganic layer, an organic layer or a composite material layer.

The color filter layer CFL may include first to third filters CF-B, CF-G and CF-R. The first to third color filters CF-B, CF-G and CF-R may be respectively arranged correspondingly to the first to third light emitting elements ED-1, ED-2 and ED-3. For example, the first filter CF-B may be a blue filter, the second filter CF-G may be a green filter, and the third filter CF-R may be a red filter. The first to third filters CF-B, CF-G and CF-R may be arranged corresponding to the first to third pixel areas PXA-B, PXA-G and PXA-R, respectively.

Each of the first to third filters CF-B, CF-G and CF-R may include a photosensitive polymer resin and a pigment or dye. The first filter CF-B may include a blue pigment or a blue dye, the second filter CF-G may include a green pigment or a green dye, and the third filter CF-R may include a red pigment or a red dye. However, one or more embodiments of the present disclosure is not limited thereto, and the first filter CF-B may not include (e.g., may exclude) the pigment or dye. The first filter CF-B may include a photosensitive polymer resin and not include a pigment or dye. The first filter CF-B may be transparent. The first filter CF-B may be formed utilizing a transparent photosensitive resin.

The color filter layer CFL may further include a buffer layer BFL. For example, the buffer layer BFL may be a protection layer protecting the first to third filters CF-B, CF-G and CF-R. The buffer layer BFL may be an inorganic layer including at least one inorganic material selected from among silicon nitride, silicon oxide and silicon oxynitride. The buffer layer BFL may be formed as a single layer or multiple layers.

In one or more embodiments, the second filter CF-G and the third filter CF-R may be yellow filters. The second filter CF-G and the third filter CF-R may be provided in one body without distinction.

In one or more embodiments, the color filter layer CFL may further include a light blocking part. The light blocking part may be a black matrix. The light blocking part may be formed by including an organic light blocking material or an inorganic light blocking material, including a black pigment or black dye. The light blocking part may prevent or reduce light leakage and may divide the boundaries among adjacent filters CF-B, CF-G and CF-R.

FIG. 4B is a cross-sectional view according to one or more embodiments of a display device DD-1 of the present disclosure. In the explanation on FIG. 4B, the overlapping contents as the contents explained referring to FIG. 1 to FIG. 4A will not be explained again, and the difference will be mainly explained.

Compared to FIG. 4A, FIG. 4B differs in terms of the positions arranged of the hole transport regions HTR-1, HTR-2 and HTR-3, and the electron transport regions ETR-1, ETR-2 and ETR-3. Referring to FIG. 4B, each of the light emitting elements ED-1, ED-2 and ED-3 may include a first electrode EL1, hole transport regions HTR-1, HTR-2 and HTR-3 arranged on the first electrode EL1, emission layers EML-B, EML-G and EML-R arranged on the hole transport regions HTR-1, HTR-2 and HTR-3, electron transport regions ETR-1, ETR-2 and ETR-3 arranged on the emission layers EML-B, EML-G and EML-R, and a second electrode EL2 arranged on the electron transport regions ETR-1, ETR-2 and ETR-3. The emission layers EML-B, EML-G and EML-R may be arranged between the first electrode EL1 and the electron transport regions ETR-1, ETR-2 and ETR-3, and the hole transport regions HTR-1, HTR-2 and HTR-3 may be arranged between the first electrode EL1 and the emission layers EML-B, EML-G and EML-R.

FIG. 5A to FIG. 5D are cross-sectional views showing light emitting elements ED, ED-a, ED-b and ED-c of embodiments. Referring to FIG. 5A to FIG. 5D, the light emitting elements ED, ED-a, ED-b and ED-c may include a first electrode EL1, a second electrode EL2 arranged on the first electrode EL1, and at least one functional layer FL arranged between the first electrode EL1 and the second electrode EL2. The at least one functional layer FL may include a hole transport region HTR, an emission layer EML, and an electron transport region ETR.

At least one selected from among the light emitting elements ED and ED-a, explained referring to FIG. 5A and FIG. 5B, may be applied to at least one selected from among the first to third light emitting elements ED-1, ED-2 and ED-3, shown in FIG. 4A by the same manner. At least one selected from among the light emitting elements ED-b and ED-c, explained referring to FIG. 5C and FIG. 5D may be applied to at least one selected from among the first to third light emitting elements ED-1, ED-2 and ED-3, shown in FIG. 4B by the same manner.

Referring to FIG. 5A and FIG. 5B, the light emitting elements ED and ED-a may include a first electrode EL1, an electron transport region ETR, an emission layer EML, a hole transport region HTR, and a second electrode EL2, stacked in order.

Referring to FIG. 5A, the hole transport region HTR may include a hole injection layer HIL and a hole transport layer HTL. The hole transport layer HTL may be arranged on the emission layer EML, and the hole injection layer HIL may be arranged on the hole transport layer HTL. The electron transport region ETR may include an electron injection layer EIL and an electron transport layer ETL. The electron injection layer EIL may be arranged on the first electrode EL1, and the electron transport layer ETL may be arranged on the electron injection layer EIL, and the emission layer EML may be arranged on the electron transport layer ETL. In the light emitting element ED, the electron transport region ETR may include the metal nanoparticles NP of one or more embodiments.

Compared to the light emitting element ED of FIG. 5A, the light emitting element ED-a of FIG. 5B is different in that the hole transport region HTR further includes an electron blocking layer EBL, and the electron transport region ETR further includes a hole blocking layer HBL. The electron blocking layer EBL may be arranged on the emission layer EML. The electron blocking layer EBL may be arranged between the emission layer EML and the hole transport layer HTL. The hole blocking layer HBL may be arranged on the electron transport layer ETL. The hole blocking layer HBL may be arranged between the emission layer EML and the electron transport layer ETL. Different from the drawing, at least one selected from among the electron blocking layer EBL and the hole blocking layer HBL may not be provided. In the light emitting element ED-a, the electron transport region ETR may include the metal nanoparticles NP of one or more embodiments.

Compared to the light emitting elements ED and ED-a, shown in FIG. 5A and FIG. 5B, there is a difference in terms of only arranged positions of a hole transport region HTR and an electron transport region ETR in the light emitting elements ED-b and ED-c, shown in FIG. 5C and FIG. 5D. Referring to FIG. 5C and FIG. 5D, the light emitting elements ED-b and ED-c may include a first electrode EL1, a hole transport region HTR, an emission layer EML, an electron transport region ETR and a second electrode EL2, stacked in order.

Referring to FIG. 5C, the hole transport region HTR may include a hole injection layer HIL and a hole transport layer HTL. The hole injection layer HIL may be arranged on the first electrode EL1, and the hole transport layer HTL may be arranged on the hole injection layer HIL. The electron transport region ETR may include an electron injection layer EIL and an electron transport layer ETL. The electron transport layer ETL may be arranged on the emission layer EML, and the electron injection layer EIL may be arranged on the electron transport layer ETL. In the light emitting elements ED-b and ED-c, the electron transport region ETR may include the metal nanoparticles NP of one or more embodiments.

Referring to FIG. 5A to FIG. 5D, the electron transport region ETR may include the metal nanoparticles NP of one or more embodiments. At least one selected from among the electron injection layer EIL, the electron transport layer ETL and the hole blocking layer HBL may include the metal nanoparticles NP of one or more embodiments. For example, the electron transport layer ETL may include the metal nanoparticles NP of one or more embodiments. In one or more embodiments, at least one selected from among the hole blocking layer HBL and the electron injection layer EIL may include the metal nanoparticles NP of one or more embodiments. In one or more embodiments, the hole blocking layer HBL, the electron transport layer ETL and the electron injection layer EIL may include the metal nanoparticles NP of one or more embodiments. The electron transport region ETR including the metal nanoparticles NP of one or more embodiments may have improved electron injection properties and/or electron transport properties and thus may contribute to the improvement of the light efficiency and the lifetime of the light emitting elements ED, ED-a, ED-b and ED-c. The metal nanoparticle NP of one or more embodiments will be explained in more detail later.

The emission layer EML may include a quantum dot QD-C. Hereinafter, the same explanation on the first to third quantum dots QD-C1, QD-C2 and QD-C3, shown in FIG. 4a and FIG. 4B will be applied to the quantum dot QD-C.

In the description, the quantum dot QD-C may refer to the crystal of a semiconductor compound. The quantum dot QD-C may be configured to emit light of one or more suitable wavelengths according to the size of the crystal. The diameter of the quantum dot QD-C may be, for example, about 1 nm to about 10 nm.

The quantum dot QD-C may be synthesized by a chemical bath deposition, a metal organic chemical vapor deposition, a molecular beam epitaxy or a similar process therewith. The chemical bath deposition is a method of growing quantum dot QD-C particle crystal after mixing an organic solvent and a precursor material. During the growth of the crystal, the organic solvent naturally plays the role of a dispersant coordinated at the surface of the quantum dot QD-C crystal and may control the growth of the crystal. Accordingly, the chemical bath deposition is more favorable than a vapor deposition method such as a metal organic chemical vapor deposition (MOCVD) and/or a molecular beam epitaxy (MBE), and may control the growth of the quantum dot QD-C particle through a relatively low cost process.

Examples of the quantum dot may include II-VI group semiconductor compounds, I-II-VI group semiconductor compounds, II-IV-VI group compounds, I-II-IV-VI group semiconductor compounds, III-V group semiconductor compounds, III-VI group semiconductor compounds, I-III-VI group semiconductor compounds, IV-VI group semiconductor compounds, II-IV-V group semiconductor compounds, IV group elements or compounds, and arbitrary combinations thereof. In the description, the “group” refers to the group in an IUPAC periodic table.

Examples of the II-VI group compound may include: a binary compound such as CdS, CdSe, CdTe, ZnS, ZnSe, ZnTe, ZnO, HgS, HgSe, HgTe, MgSe, and/or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound such as CdZnSeS, CdZnSeTe, CdZnSTe, CdHgSeS, CdHgSeTe, CdHgSTe, HgZnSeS, HgZnSeTe, and/or HgZnSTe; and/or combinations (e.g., any suitable combinations) thereof.

In one or more embodiments, the II-VI group semiconductor compound may further include a metal in group I and/or an element in group IV. The I-II-VI group compound may be selected from among CuSnS and/or CuZnS, and the II-IV-VI group compound may be selected from among ZnSnS, and/or the like The I-II-IV-VI group compound may be selected from among quaternary compounds selected from among the group including (e.g., consisting of) Cu₂ZnSnS₂, Cu₂ZnSnS₄, Cu₂ZnSnSe₄, Ag₂ZnSnS₂ and mixtures thereof.

Examples of the III-V group semiconductor compound may include: a binary compound such as GaN, GaP, GaAs, GaSb, AlN, AIP, AIAs, AISb, InN, InP, InAs, and/or InSb; a ternary compound such as GaNP, GaNAs, GaNSb, GaPAs, GaPSb, AlNP, AlNAs, AlNSb, AIPAs, AIPSb, InGaP, InNP, InAIP, InNAs, InNSb, InPAs, and/or InPSb; a quaternary compound such as GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, and/or InAIPSb; and/or combinations thereof. In one or more embodiments, the III-V group semiconductor compound may further include a II group element. Examples of the III-V group semiconductor compound including the element in group II may include InZnP, InGaZnP, InAIZnP, and/or the like.

Examples of the III-VI group semiconductor compound may include: a binary compound such as GaS, Ga₂S₃, GaSe, Ga₂Se₃, GaTe, InS, InSe, In₂Se₃, and/or InTe; a ternary compound such as InGaS₃ and/or InGaSe₃; and/or combinations thereof.

Examples of the I-III-VI group semiconductor compound may include: a ternary compound such as AgInS, AgInS₂, AgInSe₂, AgGaS, AgGaS₂, AgGaSe₂, CuInS, CulnS₂, CulnSe₂, CuGaS₂, CuGaSe₂, CuGaO₂, AgGaO₂, and/or AgAO₂; a quaternary compound such as AgInGaS₂ and/or CulnGaS₂; and/or combinations thereof.

Examples of the IV-VI group semiconductor compound may include: a binary compound such as SnS, SnSe, SnTe, PbS, PbSe, and/or PbTe; a ternary compound such as SnSeS, SnSeTe, SnSTe, PbSeS, PbSeTe, PbSTe, SnPbS, SnPbSe, and/or SnPbTe; a quaternary compound such as SnPbSSe, SnPbSeTe, and/or SnPbSTe; and/or combinations thereof.

Examples of the II-IV-V group semiconductor compound may be a ternary compound selected from among the group including (e.g., consisting of) ZnSnP, ZnSnP₂, ZnSnAs₂, ZnGeP₂, ZnGeAs₂, CdSnP₂, CdGeP₂ and mixtures thereof.

Examples of the IV group element or compound may include: a single element compound such as Si, and/or Ge; a binary compound such as SiC and/or SiGe; and/or combinations thereof.

Each element included in a polynary compound such as the binary compound, the ternary compound, and/or the quaternary compound may be present at a substantially uniform concentration or a substantially non-uniform concentration in a particle. For example, the chemical formulae refer to the types (kinds) of elements included in the compound, and the element ratio in the compound may be different. For example, AgInGaS₂ may refer to AgInₓGa₁₋ₓS₂ (x is a real number of 0 to 1).

In one or more embodiments, the quantum dot QD-C may have a single structure in which the concentration of each element included in the quantum dot QD-C is substantially uniform, or a double structure of core-shell. For example, the material included in the core and the material included in the shell may be different.

The shell of the quantum dot QD-C may play the role of a protection layer for preventing or reducing the chemical deformation of the core and maintaining semiconductor properties and/or a charging layer for providing the quantum dot with electrophoresis properties. The shell may be a single layer or a multilayer. In the core/shell structure, the shell may have a concentration gradient in which the concentration of an element present in the shell is reduced toward the core.

Examples of the shell of the quantum dot QD-C may include a metal or non-metal oxide, a semiconductor compound, and/or combinations thereof. Examples of the metal or non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO; a ternary compound such as MgAl₂O₄, CoFe₂O₄, NiFe₂O₄ and/or CoMn₂O₄; and/or combinations thereof. Examples of the semiconductor compound may include III-VI group semiconductor compounds; II-VI group semiconductor compounds; III-V group semiconductor compounds; III-VI group semiconductor compounds; I-III-VI group semiconductor compounds; IV-VI group semiconductor compounds; and/or combinations thereof, as described in this description. Examples of the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AIAs, AIP, AISb, and/or the like, and/or combinations thereof.

Each element included in the polynary compound such as the binary compound and/or the ternary compound may be present at substantially uniform concentration or substantially non-uniform concentration in a particle. For example, the chemical formulae refer to the types (kinds) of elements included in the compound, and the element ratio in the compound may be different.

The quantum dot QD-C may have a full width of half maximum (FWHM) of emission wavelength spectrum of about 45 nm or less, about 40 nm or less, or about 30 nm or less. Within this range, color purity or color reproducibility may be improved. In one or more embodiments, light emitted via such quantum dot QD-C is configured to be emitted in all directions, and light view angle may be improved. In one or more embodiments, the type or kind of the quantum dot QD-C may be spherical, pyramidal, multi-arm, cubic nanoparticle, nanotube, nanowire, nanofiber, nanoplate particle, and/or the like may be utilized.

By controlling the size of the quantum dot QD-C or by controlling the element ratio in the compound constituting the quantum dot QD-C, energy band gap may be controlled or selected, and one or more suitable wavelength bands of light may be obtained from an emission layer EML including the quantum dot QD-C. Accordingly, by utilizing such quantum dot QD-C(by utilizing quantum dots having different sizes or by controlling an element ratio in a quantum dot compound differently), light emitting elements ED, ED-a, ED-b and ED-c emitting one or more suitable wavelengths of light may be accomplished. For example, the size of the quantum dot QD-C or the element ratio in the compound constituting the quantum dot QD-C may be selected to emit red, green and/or blue light. In one or more embodiments, the quantum dots QD-C may be provided to combine one or more suitable emission colors to emit white light.

FIG. 6 is a diagram showing a metal nanoparticle NP of one or more embodiments. The metal nanoparticle NP of an embodiment may include a core MC and a ligand LD bonded to the core MC. In FIG. 6, five ligands LD are illustrative, and the number of the ligands LD is not limited thereto. In one or more embodiments, the bonding positions of the ligands LD, shown in FIG. 6 are illustrative, and one or more embodiments of the present disclosure is not limited thereto.

In one or more embodiments, the core MC of the metal nanoparticle NP may include a metal oxide. The core MC of the metal nanoparticle NP may include a quaternary metal oxide composed of four components. The core MC of the metal nanoparticle NP may include a metal oxide composed of zinc (Zn), magnesium (Mg), a first component and oxygen (O). The first component may be a component having a standard reduction potential higher than the standard reduction potential of zinc. By providing the first component having a standard reduction potential higher than the standard reduction potential of zinc, the intrinsic defects of the core MC may be eliminated.

The first component may include sodium (Na) or lithium (Li). For example, the core MC of the metal nanoparticle NP may include a quaternary metal oxide composed of zinc, magnesium, sodium and oxygen. Differently, the core MC of the metal nanoparticle NP may include a quaternary metal oxide composed of zinc, magnesium, lithium and oxygen.

The core MC of the metal nanoparticle NP may include a metal oxide represented by Formula M-1. Formula M-1 may be composed of zinc, magnesium, a first component and oxygen.

Znₓ₁Mg_{y1}Q_{z1}O Formula M-1

In Formula M-1, Q may be Na or Li. Q may correspond to the above-described first component.

The sum of x1, y1 and z1 may be 1. For example, x1+y1+z1=1 may be satisfied. x1 may be a real number greater than 0 and at most 0.95, y1 may be a real number greater than 0 and at most 0.3, and z1 may be a real number greater than 0 and at most 0.3.

In the comparable metal nanoparticle, the core may include zinc oxide (ZnO) or zinc magnesium oxide (ZnMgO). Zinc oxide and zinc magnesium oxide include intrinsic defects like zinc vacancy (Vzn) and/or the like, and the defects induced exciton quenching phenomenon and substantially non-uniform injection of holes/electrons. Accordingly, the comparable metal nanoparticle including zinc oxide as the core deteriorated the lifetime and efficiency of a light emitting element.

In addition, if zinc oxide and zinc magnesium oxide is exposed to oxygen and/or moisture, a reverse reaction may be induced, and gelation or agglomeration due to the short distance among particles may occur. Accordingly, the discharge stability and stability over time of zinc oxide and zinc magnesium oxide may be degraded, and the provision by an inkjet printing method or a dispensing method may be inappropriate.

In contrast, the core MC of the metal nanoparticle NP of one or more embodiments includes the first component (that is, sodium or lithium), and the intrinsic defects of the core MC may be eliminated or reduced. Due to the elimination of the defect site of the first component, the deterioration of the lifetime and efficiency of the light emitting elements ED, ED-a, ED-b and ED-c (FIG. 5A to FIG. 5D) due to the intrinsic defects of the core MC may be prevented or reduced. Accordingly, the light emitting elements ED, ED-a, ED-b and ED-c (FIG. 5A to FIG. 5D) including the metal nanoparticles NP of one or more embodiments may show excellent or suitable light efficiency and lifetime. In one or more embodiments, because the metal nanoparticle NP of one or more embodiments includes the ligand LD bonded to the core MC, gelation and agglomeration may be prevented or reduced, and excellent or suitable stability over time and discharge stability may be shown.

The ligand LD of the metal nanoparticle NP may be derived from an ionic compound represented by Formula 1. The ionic compound represented by Formula 1 may include a Na⁺ ion and an O⁻ ion constituting a glycolate moiety.

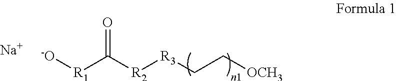

In Formula 1, R₁ may be a direct linkage or an unsubstituted methylene group. R₂ and R₃ may each independently be a direct linkage, —O—*, or a substituted or unsubstituted methylene group. For example, at least one selected from among R₂ and R₃ may be a direct linkage, and the remainder may be —O—*, an unsubstituted methylene group, or a methylene group substituted with a hydroxyl group.

n1 may be an integer of 1 to 5. In Formula 1, O⁻ adjacent to Na⁺ and directly bonded to R₁, a carbonyl (C═O) group, and —O— in —OCH₃ at the other end (e.g., an opposite end) may constitute a glycolate moiety.

Formula 1 may be represented by Formula 1-1 or Formula 1-2. Formula 1-1 represents a case of Formula 1 where R₁ is a direct linkage. Formula 1-2 represents a case of Formula 1 where R₁ is an unsubstituted methylene group.

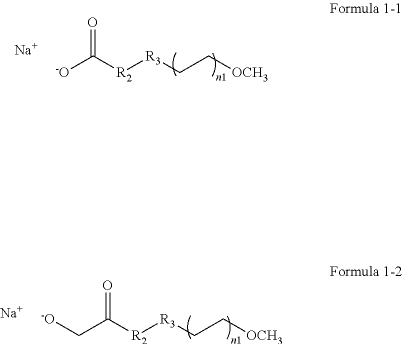

In Formula 1-1 and Formula 1-2, the same contents explained in Formula 1 may be applied for n1, R₂ and R₃. For example, the metal nanoparticle NP of one or more embodiments may include a ligand LD derived from an ionic compound represented by at least one selected from among 1-A to 1-C. The ionic compound represented by Formula 1-B may represent a sodium-(2-methoxyethyl)glycolate complex.

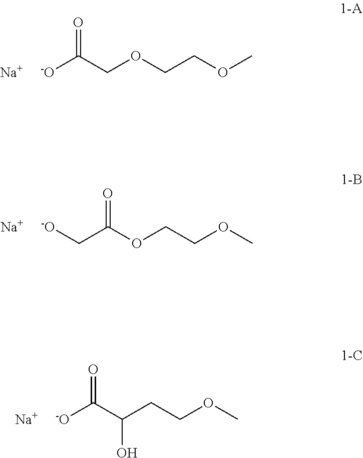

Referring to FIG. 6, the ligand LD may include a first ligand LD1 and a second ligand LD2. The ligand LD derived from the ionic compound represented by Formula 1 may include the first ligand LD1 and the second ligand LD2, formed through the dissociation of the ionic bond in the ionic compound of Formula 1. The first ligand LD1 may include the Na⁺ ion of Formula 1, and the second ligand LD2 may include the O⁻ ion of Formula 1. For example, the second ligand LD2 may include O⁻, oxygen bonded to O⁻ and a carbon chain in Formula 1. For example, the second ligand LD2 may be represented by Formula 2. Formula 2 may be one obtained by the dissociation of the Na⁺ ion from the ionic compound represented by Formula 1.

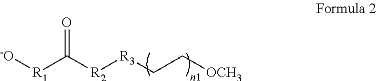

In Formula 2, the same contents explained in Formula 1 may be applied for n1 and R₁ to R₃.

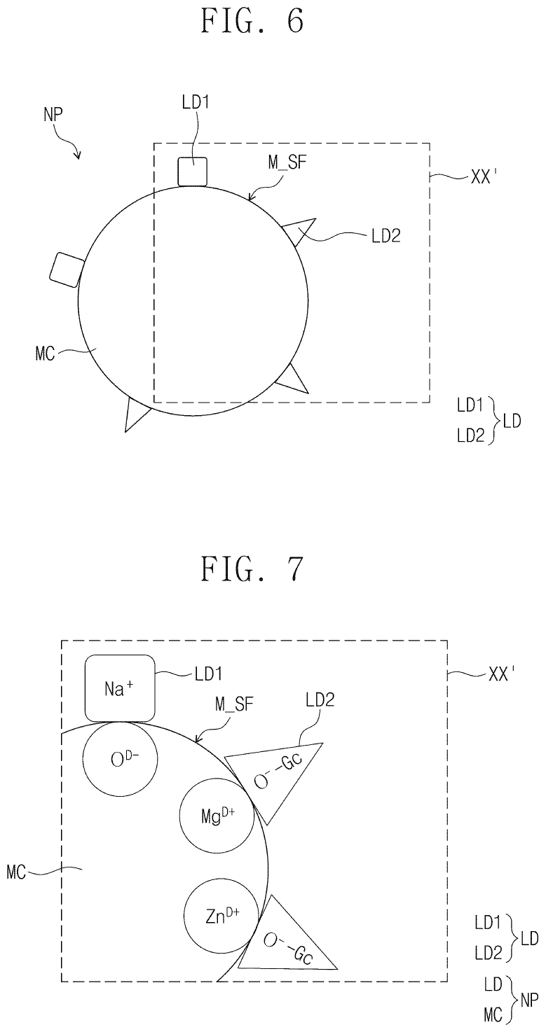

In the metal nanoparticle NP, the first ligand LD1 and the second ligand LD2 may be respectively bonded to the surface M_SF of the core MC. FIG. 7 is an enlarged diagram of region XX′ in FIG. 6. FIG. 7 particularly shows the ligand LD bonded to the surface M_SF of the core MC.

At the surface M_SF of the core MC, the component of the metal oxide included in the core MC may be exposed. As described above, in the metal nanoparticle NP, the core MC may include a metal oxide composed of zinc, magnesium, a first component and oxygen. At the surface M_SF of the core MC, zinc, magnesium and oxygen may be exposed, and the ligand LD may be bonded to at least one selected from among the exposed zinc, magnesium and oxygen. The first ligand LD1 may be bonded to the oxygen at the surface M_SF of the core MC. The second ligand LD2 may be bonded to at least one selected from among the zinc and the magnesium at the surface M_SF of the core MC.

Each of the zinc, magnesium and oxygen exposed at the surface M_SF of the core MC may include a dangling bond. In FIG. 7, the dangling bonds of the zinc, magnesium and oxygen are represented by OD^{D-}, Mg^{D+}, and Zn^{D+}, respectively. The dangling bonds are the outermost electrons not participating in the bonding and correspond to the surface defects of the core MC, and the surface defects of the core MC may be eliminated via the bonding with the ligand LD. The first ligand LD1 including the Na⁺ ion may be combined with the oxygen dangling bond (O^{D-}) at the surface of the core MC, and the second ligand LD2 including the O⁻ ion may be combined with at least one selected from among the zinc dangling bond (Zn^{D+}) and the magnesium dangling bond (Mg^{D+}) at the surface M_SF of the core MC. In FIG. 7, the second ligand LD2 is represented by O⁻—Gc, and this may correspond to the above-described Formula 2.

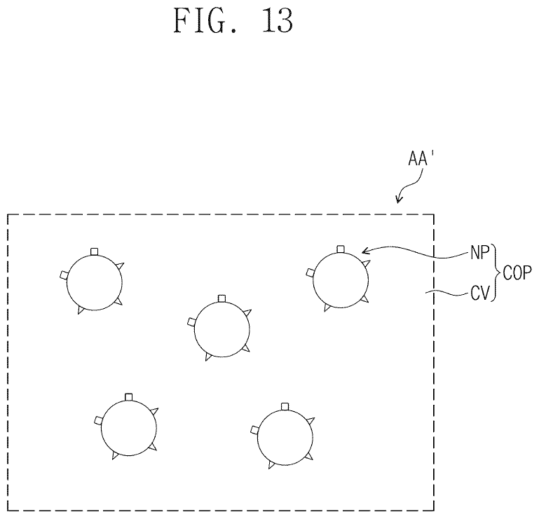

The metal nanoparticle NP in which the ligand LD is bonded to the surface M_SF of the core MC may not arise gelation and agglomeration, and show excellent or suitable stability over time and discharge stability. In one or more embodiments, in the method for manufacturing a display device of one or more embodiment, which will be explained in more detail later, a composition COP (FIG. 13) including the metal nanoparticles NP may be provided by an inkjet printing method or a dispensing method. The composition COP (FIG. 13) may further include a first solvent CV (FIG. 13) in which the metal nanoparticles NP are dispersed. The composition COP (FIG. 13) will be explained in more detail later.

In one or more embodiments, based on about 100 wt % of the total weight of the metal nanoparticles NP, the weight of an organic component present at the surface M_SF of the core MC may be about 15 wt % to about 25 wt %. In the description, the weight of a surface organic component refers to the weight of the organic component present at the surface M_SF of the core MC, and the weight of the surface organic component was measured by a thermogravimetric analysis (TGA) method. The weight of the surface organic component may refer to the weight of an organic component at the surface M_SF of the core MC in the metal nanoparticles NP. The weight of the surface organic component may include the weight of the components constituting the ligand LD in the metal nanoparticles NP.

In the metal nanoparticles, if the weight of the surface organic component is less than about 15 wt %, the surface defects may not be eliminated or reduced, and the light efficiency and lifetime of the light emitting element including the metal nanoparticles may be deteriorated. In one or more embodiments, in the metal nanoparticles, if the weight of the surface organic component is less than about 15 wt %, dispersibility may be degraded, and the metal nanoparticles may not be dispersed in a solvent and may not be provided by an inkjet printing method or a dispensing method. In the metal nanoparticles, if the weight of the surface organic component is greater than about 25 wt %, electron transport properties and electron injection properties may be degraded. Differently, in one or more embodiments, the metal nanoparticles NP having the weight of the surface organic component of about 15 wt % to about 25 wt % may show excellent or suitable electron transport properties and electron injection properties, and the light efficiency and lifetime of the light emitting elements ED, ED-a, ED-b and ED-c (FIG. 5A to FIG. 5D) may be improved. In one or more embodiments, the metal nanoparticles NP having the weight of the surface organic component of about 15 wt % to about 25 wt % may show excellent or suitable dispersibility with respect to the solvent and may be provided by an inkjet printing method or a dispensing method.

In one or more embodiments, the absolute quantum efficiency of the metal nanoparticles NP may be about 10% or less. In the description, the absolute quantum efficiency was measured from the metal nanoparticles in a liquid phase utilizing a QE-2100 equipment of Otsuka Co. The absolute quantum efficiency is emission efficiency in the wavelength region of visible light produced according to the surface defects of the metal nanoparticles, and a greater value refers to greater surface defects. In the metal nanoparticles, if the surface defects increase, the light efficiency of a light emitting element may be degraded.

The metal nanoparticles having the absolute quantum efficiency of greater than about 10% have significant surface defects, and a light emitting element including the metal nanoparticles having the absolute quantum efficiency of greater than about 10% induces exciton quenching and shows relatively low light efficiency. In one or more embodiments, the metal nanoparticles NP having the absolute quantum efficiency of about 10% or less have fewer (e.g., significantly fewer) surface defects and may improve the light efficiency of the light emitting elements ED, ED-a, ED-b and ED-c (FIG. 5A to FIG. 5D).

The metal nanoparticles of the Comparative Examples and the Example were evaluated and shown in Table 1. For example, in Table 1, the absolute quantum efficiency, photoluminescence reduction ratio, weight of surface organic component, and average particle size over time for metal nanoparticles, compositions including metal nanoparticles, and light emitting elements manufactured utilizing the compositions including the metal nanoparticles, were evaluated and shown.

The absolute quantum efficiency was measured by providing metal nanoparticles in a liquid phase and was measured utilizing a QE-2100 equipment of Otsuka Co. The photoluminescence (PL) reduction ratio shows a photoluminescence reduction ratio produced in a single layer of a reference example (Ref.) including only an emission layer, if the metal nanoparticles are coated on the emission layer. The reference example does not include metal nanoparticles and includes only quantum dots configured to produce green light. The Comparative Examples and the Examples include an emission layer and an electron transport layer, include metal nanoparticles in the electron transport layer, and include quantum dots configured to emit green light in the emission layer like the reference example. If the surface defects of the metal nanoparticles increase, it may suggest that the photoluminescence reduction ratio increases, and the light efficiency and lifetime of the light emitting element are deteriorated.

The emission layer of the reference example utilized InP as the quantum dots configured to emit green light, and the InP was dispersed in a solvent and provided by a spin coating method for coating into a thickness of about 400 Å. Then, the solvent was dried by heating at about 140° C. for about 10 minutes to form (or provide) an emission layer, and photoluminescence intensity was measured utilizing a FluoroMax Plus equipment. In the Comparative Examples and the Example, an electron transport layer including metal nanoparticles and an emission layer including InP were formed by the same method as that for forming (or providing) the emission layer of the reference example, and photoluminescence intensity was measured utilizing the FluoroMax Plus equipment.

The weight of the surface organic component was measured by a thermogravimetric analysis. The average particle size was measured by providing metal nanoparticles and measuring the size of the particles after 0 days, 3 days, 5 days, or 14 days by utilizing a dynamic light scattering method. The average particle size after the lapse of 0 days, represents the average particle size of the metal nanoparticles, measured immediately after providing the metal nanoparticles.

The metal nanoparticle of Comparative Example 1 includes a metal oxide composed of zinc, magnesium and oxygen as a core, and does not include a ligand derived from the ionic compound represented by Formula 1. The metal nanoparticle of Comparative Example 2 includes a metal oxide composed of zinc, magnesium, sodium and oxygen as a core, and does not include a ligand derived from the ionic compound represented by Formula 1. The metal nanoparticle of Example 1 includes a metal oxide composed of zinc, magnesium, sodium and oxygen as a core, and a first ligand and a second ligand derived from the ionic compound represented by 1-B above as ligands. The metal nanoparticle of Example 1 includes sodium as a first component.

In Table 1, the average particle size (or particle diameter) of the metal nanoparticles of Comparative Example 1 after 3 days was about 300 nanometer (nm). The average particle size of the metal nanoparticles of Comparative Example 2 after 5 days was about 300 nm. The average particle size of the metal nanoparticles of Example 1 after 14 days was about 13.2 nm.

TABLE 1

| | | Photolumi- | | | |
|---|---|---|---|---|---|
| | | nescence | | | |
| | Absolute | reduction | Weight of | | |
| | quantum | ratio | surface | Average particle | |
| | efficiency | (PL | organic | size (nm) | |
| | (PL_QY, | reduction | component | 0 | 14 |
| | %) | ratio) | (wt %) | days | days |
| Comparative | 48 | −61% | 16 | 13.3 | 300 (3 |
| Example 1 | | | | | days) |
| Comparative | 10 | −39% | 16.2 | 12.0 | 300 (5 |
| Example 2 | | | | | days) |
| Example 1 | 4 | −25% | 20 | 12.2 | 13.2 |

Referring to Table 1, it can be found that Example 1 shows the absolute quantum efficiency of about 10% or less and a relatively small photoluminescence reduction ratio. Example 1 includes the metal nanoparticles according to one or more embodiments, and the metal nanoparticle in Example 1 includes a metal oxide composed of zinc, magnesium, sodium and oxygen as a core and a ligand derived from the ionic compound represented by Formula 1. Accordingly, it can be found that the light emitting element including the metal nanoparticles of one or more embodiments shows excellent or suitable light efficiency and lifetime.

In one or more embodiments, it can be found that the weight of the surface organic component was about 15 wt % to about 25 wt % and good or suitable in Comparative Example 1, Comparative Example 2 and Example 1. In one or more embodiments, the metal nanoparticles having the weight of the surface organic component of about 15 wt % to about 25 wt % may show excellent or suitable dispersibility and excellent or suitable electron injection properties/transport properties.

Referring to the average particle sizes in Table 1, it can be found that the average particle size difference between after 0 days and after 14 days is relatively small in Example 1. For example, the gelation and agglomeration of the metal nanoparticles did not occur in Example 1, and excellent or suitable stability over time was shown. The metal nanoparticles showing excellent or suitable stability over time may be provided by an inkjet printing method or a dispensing method.

In one or more embodiments, the average particle size of the metal nanoparticles of Comparative Example 1 increased about 20 times or more after 3 days, and the average particle size of the metal nanoparticles of Comparative Example 2 increased about 20 times or more after 5 days, which suggests that the average particle size increased due to the agglomeration of the particles. Without being bound by any particular theory, it is believed that the metal nanoparticles of Comparative Examples 1 and 2 do not include a ligand derived from the ionic compound represented by Formula 1, and the agglomeration of the particles occurred, because the distance among the particles was short. The modified metal nanoparticles like this may be a factor deteriorating discharge stability if a composition including the metal nanoparticles is provided by an inkjet printing method or a dispensing method.

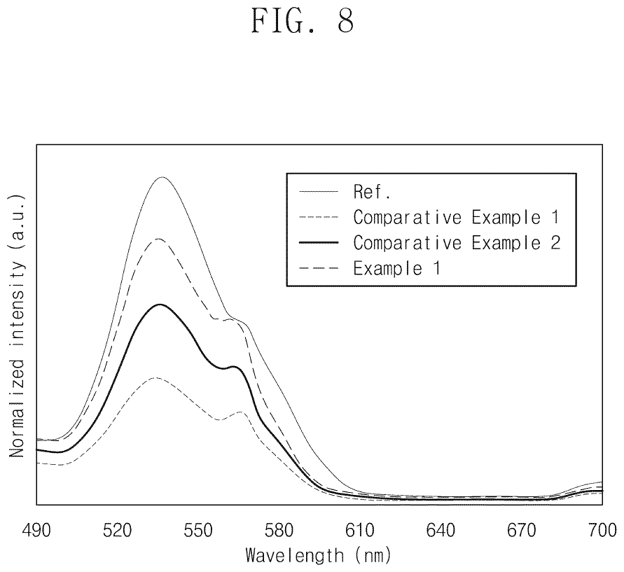

FIG. 8 is a graph showing the normalized intensity of photoluminescence intensity in a visible light wavelength region in the Comparative Examples and the Example, and showing relative values (a.u.: arbitrary unit) with respect to a reference example (Ref.). The photoluminescence reduction ratio in Table 1 may be a value relating to the graph in FIG. 8.

Referring to FIG. 8, it can be found that Example 1 shows high photoluminescence intensity compared to Comparative Examples 1 and 2. It can be found that Example 1 has a small photoluminescence reduction ratio compared to the reference example including only an emission layer. The metal nanoparticles of Example 1 include a metal oxide composed of zinc, magnesium, sodium and oxygen as a core and a ligand derived from the ionic compound represented by Formula 1. Accordingly, it can be found that a light emitting element including the metal nanoparticles of one or more embodiments may show excellent or suitable light efficiency.

In one or more embodiments, Comparative Example 1 includes a metal oxide not including sodium, as a core, and shows very low photoluminescence intensity and a high photoluminescence reduction ratio. The metal nanoparticle of Comparative Example 1 does not include sodium and a ligand derived from the ionic compound represented by Formula 1, and the intrinsic defects and surface defects of the core cannot be eliminated or reduced, thereby showing very low photoluminescence intensity. The metal nanoparticle of Comparative Example 2 does not include a ligand derived from the ionic compound represented by Formula 1, and the surface defects cannot be eliminated or reduced, thereby showing very low photoluminescence intensity.

In Table 2, the light efficiency and lifetime of the light emitting elements of Comparative Example 1, Comparative Example 2 and Example 1 in Table 1 are evaluated and shown. In Table 2, light efficiency at a luminance of about 1280 cd/m² and the lifetime were measured utilizing Keithley SMU 236 and a photo spectrometer PR650 are shown. The lifetime was obtained by measuring the time (hour) consumed to be about 90% of an initial luminance.

TABLE 2

| | Efficiency (cd/A) | Lifetime (T90, h) |
|---|---|---|
| Comparative Example 1 | 60.2 | 102 |
| Comparative Example 2 | 76.0 | 250 |
| Example 1 | 75.6 | 255 |

Referring to Table 2, it can be found that the light emitting elements of Comparative Example 2 and Example 1 each show relatively higher efficiency compared to the light emitting element of Comparative Example 1. It can be found that the light emitting element of Example 1 shows relatively longer lifetime compared to Comparative Examples 1 and 2. In conclusion, the light emitting element of Example 1 shows high efficiency and long-life characteristics concurrently (e.g., simultaneously). As described above, the light emitting element of Example 1 includes the metal nanoparticles of one or more embodiments, and in Example 1, the metal nanoparticle includes a core and a ligand bonded to the core. In the metal nanoparticle of Example 1, the core includes zinc, magnesium, sodium and oxygen, and the ligand is derived from the ionic compound of Formula 1. Accordingly, in one or more embodiments, the metal nanoparticle including the core including a metal oxide composed of zinc, magnesium, sodium and oxygen and the ligand bonded to the core and derived from the ionic compound of Formula 1 may improve the efficiency and lifetime of the light emitting element.

In one or more embodiments, as described above, in Comparative Example 1, the metal nanoparticles include a ternary metal oxide not including sodium as a core and do not include the ligand derived from the ionic compound represented by Formula 1. In Comparative Example 2, the metal nanoparticles include a quaternary metal oxide as a core but do not include the ligand derived from the ionic compound represented by Formula 1. Accordingly, the light emitting element of Comparative Example 1 shows relatively low efficiency and short lifetime, and Comparative Example 2 shows relatively short lifetime.

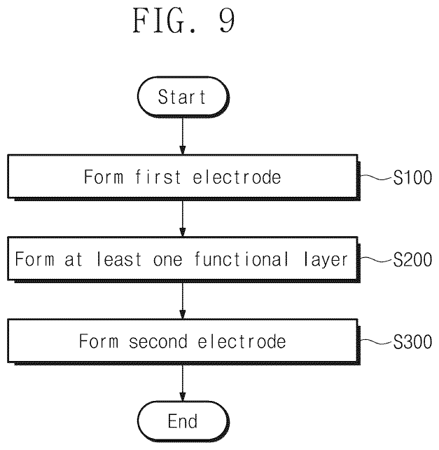

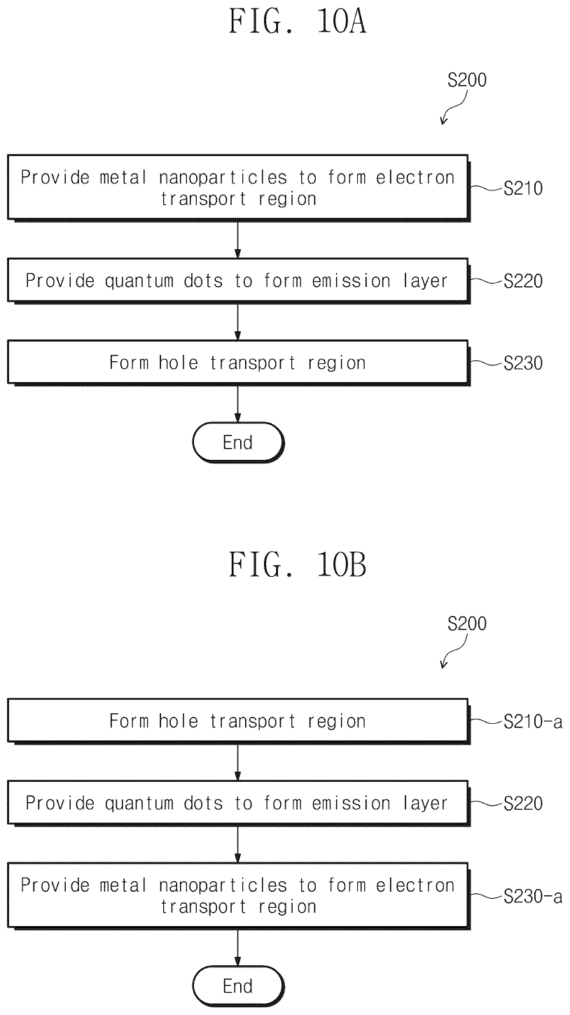

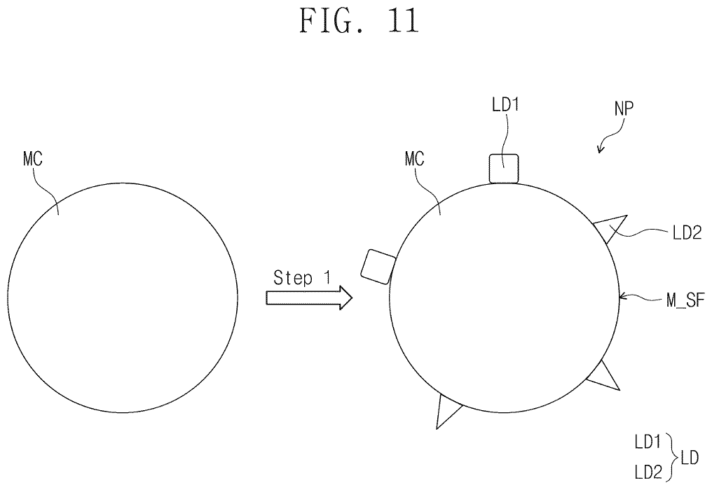

The light emitting element of one or more embodiments may be manufactured by the method for manufacturing a light emitting element of one or more embodiments. FIG. 9, FIG. 10A, and FIG. 10B are flowcharts showing the method for manufacturing the light emitting element of one or more embodiments. FIG. 11 to FIG. 13 are diagrams schematically showing the manufacturing steps of a light emitting element of one or more embodiments. Hereinafter, in the explanation on FIG. 9 to FIG. 13, the contents overlapping with the contents explained referring to FIG. 1 to FIG. 8 will not be explained again, and the difference will be mainly explained.

Referring to FIG. 9, the method for manufacturing a light emitting element of one or more embodiments may include an operation of forming (or providing) a first electrode on a base layer (S100), an operation of forming (or providing) at least one functional layer on the first electrode (S200), and an operation of forming (or providing) a second electrode on the at least one functional layer (S300). Referring to FIG. 10A and FIG. 10B, the operation of forming (or providing) the at least one functional layer (S200) may include an operation of providing quantum dots to form (or provide) an emission layer (S220), and an operation of providing metal nanoparticles to form (or provide) an electron transport region (S210 or S230-a). In one or more embodiments, the operation of forming the at least one functional layer (S200) may further include an operation of forming (or providing) a hole transport region (S230 or S210-a).

Referring to FIG. 10A, in the operation of forming (or providing) the at least one functional layer (S200), the operation of forming (or providing) the emission layer (S220) may be performed after the operation of forming (or providing) the electron transport region (S210), and the operation of forming (or providing) the hole transport region (S230) may be performed after the operation of forming (or providing) the emission layer (S220). Compared to FIG. 10A, FIG. 10B is different in that the operation of forming (or providing) the emission layer (S220) is performed prior the operation of forming (or providing) the electron transport region (S210), and operation of forming (or providing) the hole transport region (S210-a) is performed prior to the operation of forming (or providing) the emission layer (S220).

The method for manufacturing a light emitting element of one or more embodiments may include an operation of preparing metal nanoparticles NP prior to the operation of forming (or providing) the electron transport region (S210 or S230-a). FIG. 11 is a diagram schematically showing the operation of preparing metal nanoparticles NP.

The operation of preparing the metal nanoparticles NP may include an operation of preparing a core MC and an operation of providing the core MC with the ionic compound represented by Formula 1 to prepare the metal nanoparticles NP. By providing the ionic compound, a ligand LD may be bonded at the surface M_SF of the core MC. In FIG. 11, “Step 1” may represent the operation of providing the ionic compound represented by Formula 1.

In one or more embodiments, the core MC may include a metal oxide composed of zinc, magnesium, a first component and oxygen. The first component may include sodium or lithium. The operation of preparing the core MC may include an operation of preparing a mixture including a zinc precursor, a magnesium precursor, a first precursor and a solvent and an operation of providing the mixture with a third solvent including a hydroxyl group. The first component may be derived from the first precursor, and the first precursor may include a sodium precursor or a lithium precursor.

In the description, the zinc precursor is a material including zinc and a component chemically bonded to the zinc, and the chemically bonded component may refer to a component which may be easily dissociated from the zinc. The magnesium precursor may be a material including magnesium and a component chemically bonded to the magnesium, and the chemically bonded component may refer to a component which may be easily dissociated from the magnesium. The first precursor may be a material including a first component and a component chemically bonded to the first component, and the chemically bonded component may refer to a component which may be easily dissociated from the first component. For example, each of the zinc precursor, magnesium precursor, and the first precursor may be provided as a salt type or kind.

Each of the zinc precursor, magnesium precursor, and the first precursor may include an acetate ion or a halogen ion. The halogen ion may include at least one selected from among a fluorine ion, a bromine ion, a chlorine ion, and an iodine ion. Each of the acetate ion and the halogen ion may be chemically bonded to each of the zinc precursor, magnesium precursor, and the first precursor. However, one or more embodiments of the present disclosure is not limited thereto, and the zinc precursor, magnesium precursor, and the first precursor, including the materials which may be easily dissociated, may be utilized for the preparation of the core MC included in the metal nanoparticles NP.

The mixture may include a second solvent in which the zinc precursor, the magnesium precursor, and the first precursor are dissolved. The second solvent may be a polar solvent. The second solvent may include at least one selected from among water (H₂O), ethylene glycol, and dimethyl sulfoxide. However, one or more embodiments of the present disclosure is not limited thereto, and any polar solvent in which the zinc precursor, magnesium precursor, and the first precursor may be easily dissolved, may be utilized as the second solvent, without limitation.

To the mixture including the zinc precursor, the magnesium precursor, the first precursor and the second solvent, a third solvent including a hydroxyl group may be provided. The third solvent may include at least one selected from among potassium hydroxide, sodium hydroxide, trimethylammonium hydroxide (TMAM), and tetramethylammonium hydroxide (TMAH). In one or more embodiments, ethanol may be further provided together with the third solvent. Then, the core MC including the metal oxide composed of zinc, magnesium, a first component and oxygen may be formed. The first component may include sodium and lithium.

To the core MC thus formed, the ionic compound represented by Formula 1 may be provided. The surface M_SF of the core MC may be treated with the ionic compound. Accordingly, through the reaction with the zinc, magnesium and oxygen exposed to the surface M_SF of the core MC, the ligand LD may be bonded to the surface M-SF. The operation of reacting the ionic compound with the surface M_SF of the core MC may be performed at a temperature of about 25° C. to about 100° C. After the ligand LD is bonded to the core MC, excessive amounts of acetone and hexane may be provided to separate the metal nanoparticles from the product. The separated metal nanoparticles NP may be dispersed in the first solvent CV (FIG. 13), and a composition COP (FIG. 13) for forming (or providing) the electron transport region ETR (FIG. 5A to FIG. 5D) may be prepared.

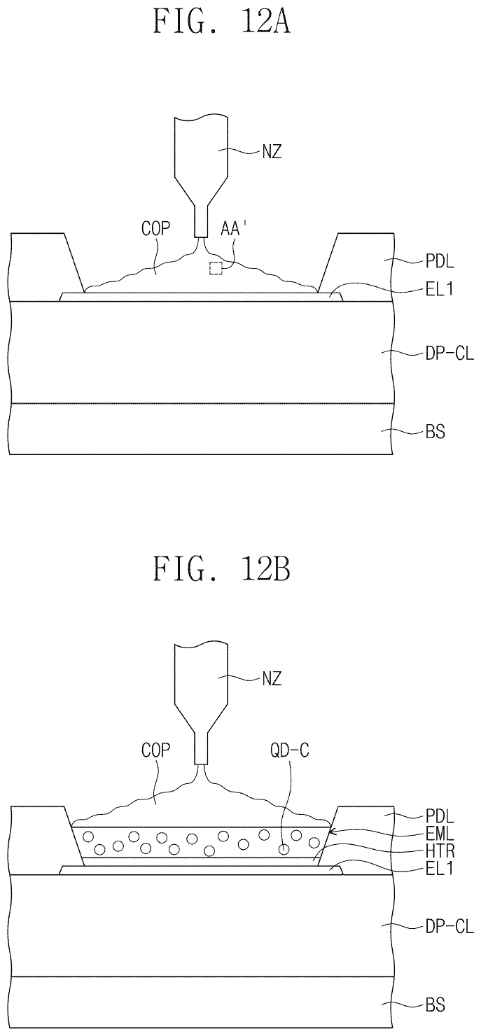

FIG. 12A is a diagram showing an operation of providing the composition COP on the first electrode EL1. The first electrode EL1 may be formed on a base layer BS. For example, the first electrode EL1 may be formed on a circuit layer DP-CL arranged on the base layer BS. FIG. 12B is a diagram showing an operation of providing the composition COP on the emission layer EML. Compared to FIG. 12A, FIG. 12B is different in that the operation of forming (or providing) the emission layer EML is performed prior to the operation of providing the composition COP. If the preparation operation shown in FIG. 12A is performed, the light emitting elements ED and ED-a, shown in FIG. 5A and FIG. 5B may be manufactured. If the preparation operation shown in FIG. 12B is performed, the light emitting elements ED-b and ED-c, shown in FIG. 5C and FIG. 5D may be manufactured.

Referring to FIG. 12B, the emission layer EML may be formed by providing a quantum dot composition including quantum dots QD-C. The quantum dot composition may include the quantum dots QD-C and a solvent in which the quantum dots QD-C are dispersed. For example, the quantum dots QD-C may be dispersed in the organic solvent and provided by an inkjet printing method or a dispensing method.

FIG. 13 is an enlarge diagram on region AA′ in FIG. 12A, and may be a diagram schematically showing the composition COP. Hereinafter, the same explanation on the composition COP may be applied for both (e.g., simultaneously) FIG. 12A and FIG. 12B. Hereinafter, the explanation will be given referring to FIG. 11 to FIG. 13 together.

In one or more embodiments, the composition COP including the metal nanoparticles NP may be provided by an inkjet printing method or a dispensing method. In one or more embodiments, the metal nanoparticle NP may include a core MC and a ligand LD bonded to the surface M_SF of the core MC. The core MC may include the metal oxide represented by Formula M-1, and the ligand LD may include first and second ligands LD1 and LD2, derived from the ionic compound represented by Formula 1. The first ligand LD1 may include a Na⁺ ion, and the second ligand LD2 may include an O⁻ ion. The first ligand LD1 may be bonded to oxygen at the surface M_SF of the core MC, and the second ligand LD2 may be bonded to at least one selected from among zinc and magnesium at the surface M_SF of the core MC. The metal nanoparticle including the first and second ligands LD1 and LD2 shows excellent or suitable stability over time, and may be provided by an inkjet printing method or a dispensing method.

In FIG. 12A and FIG. 12B, the composition COP is provided through a nozzle NZ, but the provision device of the composition COP is not limited thereto. The composition COP having excellent or suitable discharge stability and stability over time may be easily discharged without blocking the nozzle NZ.

Referring to FIG. 13, the composition COP may include a first solvent CV in which the metal nanoparticles NP are dispersed. The surface of the metal nanoparticle shows hydrophilicity, and a material showing hydrophilicity and smooth dispersion of the metal nanoparticles NP may be provided as the first solvent CV. The first solvent CV may be a material including an alkoxy group and a hydroxyl group. The first solvent CV may include a material represented by Formula S-1.

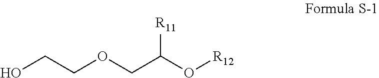

In Formula S-1, R₁₁ and R₁₂ may each independently be a hydrogen atom or a substituted or unsubstituted alkyl group of 1 to 10 carbon atoms, or combined with an adjacent group to form (or provide) a ring. For example, R₁₁ may be a hydrogen atom, an unsubstituted methyl group, an unsubstituted ethyl group, or an unsubstituted propyl group. R₁₂ may be an unsubstituted t-butyl group, an ethyl group substituted with an oxy group, an unsubstituted iso-pentyl group, an unsubstituted ethyl group, or a methyl group substituted with a phenyl group. R₁₁ and R₁₂ may be combined to form (or provide) a ring. However, these are illustrations, and one or more embodiments of the present disclosure is not limited thereto.

The first solvent CV may include a material represented by at least one selected from among S-11 to S-18. Formula S-1 may be represented by at least one selected from among S-11 to S-18.

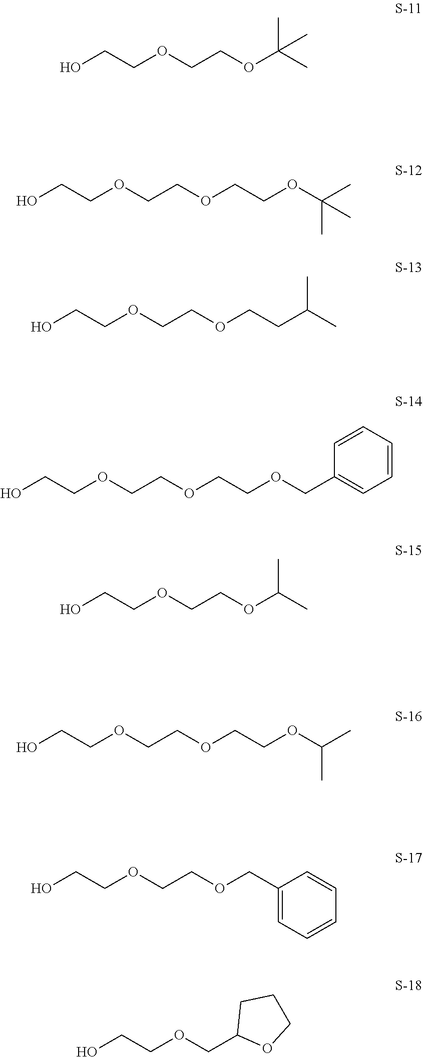

The method for manufacturing a light emitting element of one or more embodiments may include an operation of providing a composition including metal nanoparticles to form (or provide) an electron transport region, and an operation of providing quantum dots to form (or provide) an emission layer. The composition including the metal nanoparticles may be provided by an inkjet printing method or a dispensing method. The light emitting element of one or more embodiments manufactured by the method for manufacturing a light emitting element of one or more embodiments may include the electron transport region including the metal nanoparticles and the emission layer including the quantum dots. The display device of one or more embodiments may include the light emitting element of one or more embodiments.

In one or more embodiments, the metal nanoparticle may include a core and a ligand bonded to the surface of the core. The core may include a metal oxide composed of zinc, magnesium, a first component (sodium or lithium), and oxygen, and the ligand may be derived from an ionic compound including a Na⁺ ion and an O⁻ ion. The gelation and agglomeration of the metal nanoparticles including the ligand derived from the ionic compound including the Na⁺ ion and the O⁻ ion may be prevented or reduced, and an inkjet printing method or a dispensing method may be utilized for provision. In one or more embodiments, in the metal nanoparticle including the core including the first component and the ligand derived from the ionic compound, intrinsic defects and surface defects may be eliminated or reduced, and the light efficiency and lifetime of the light emitting element may be improved.

The light emitting element of one or more embodiments and the display device including the light emitting device include metal nanoparticles in which a ligand is bonded to a core, and may show high efficiency and long lifetime.

The method for manufacturing a light emitting element of one or more embodiments includes an operation of providing metal nanoparticles including a ligand and may show excellent or suitable manufacturing efficiency.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed, and equivalents thereof.

What is claimed is:

1. A light emitting element comprising:
a first electrode;
a second electrode on the first electrode; and
at least one functional layer between the first electrode and the second electrode,
wherein the at least one functional layer comprises an emission layer comprising quantum dots and an electron transport region comprising metal nanoparticles,
each of the metal nanoparticles comprises:
a core comprising a metal oxide composed of zinc (Zn), magnesium (Mg), oxygen (O), and a first component; and
a ligand bonded to the core and derived from an ionic compound represented by Formula 1, and
the first component comprises sodium (Na) or lithium (Li):
Formula 1 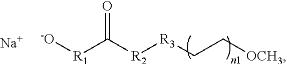
in Formula 1,
R₁ is a direct linkage or an unsubstituted methylene group,
R₂ and R₃ are each independently a direct linkage, —O—*, or a substituted or unsubstituted methylene group, and
n1 is an integer of 1 to 5.

2. The light emitting element of claim 1, wherein the metal oxide is represented by Formula M-1:
Znₓ₁Mg_{y1}Q_{z1}O, Formula M-1
in Formula M-1,
Q is Na or Li,
a sum of x1, y1 and z1 is 1,
x1 is a real number greater than 0 and at most 0.95,
y1 is a real number greater than 0 and at most 0.3, and
z1 is a real number greater than 0 and at most 0.3.

3. The light emitting element of claim 1, wherein
the ligand comprises a first ligand comprising a Na⁺ ion of Formula 1 and a second ligand comprising an O⁻ ion of Formula 1, and
each of the first ligand and the second ligand is bonded to a surface of the core.

4. The light emitting element of claim 3, wherein the first ligand is bonded to oxygen (O) at the surface.

5. The light emitting element of claim 3, wherein the second ligand is bonded to at least one selected from among zinc (Zn) and magnesium (Mg) at the surface.

6. The light emitting element of claim 1, wherein the metal nanoparticles have an absolute quantum efficiency of about 10% or less.

7. The light emitting element of claim 1, wherein the content of an organic component present at a surface of the core is about 15 wt % to about 25 wt % on the basis of about 100 wt % of the total weight of the metal nanoparticles.

8. The light emitting element of claim 1, wherein
the emission layer is between the electron transport region and the second electrode, and
the at least one functional layer further comprises a hole transport region between the emission layer and the second electrode.

9. The light emitting element of claim 1, wherein
the emission layer is between the first electrode and the electron transport region, and
the at least one functional layer further comprises a hole transport region between the first electrode and the emission layer.

10. The light emitting element of claim 1, wherein
the electron transport region comprises an electron injection layer on the first electrode, an electron transport layer on the electron injection layer, and a hole blocking layer on the electron transport layer, and
at least one selected from among the electron injection layer, the electron transport layer, and the hole blocking layer comprises the metal nanoparticles.

11. A method for manufacturing a light emitting element, the method comprising:
providing a first electrode on a base layer;
providing at least one functional layer on the first electrode; and
providing a second electrode on the at least one functional layer,
wherein the providing of the at least one functional layer comprises:
providing quantum dots to provide an emission layer; and
providing a composition comprising metal nanoparticles to provide an electron transport region,
each of the metal nanoparticles comprises:
a core comprising a metal oxide composed of zinc (Zn), magnesium (Mg), oxygen (O) and a first component; and
a ligand bonded to the core and derived from an ionic compound represented by Formula 1, and
the first component comprises sodium (Na) or lithium (Li): 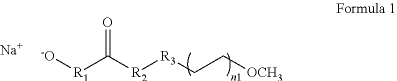
in Formula 1,
R₁ is a direct linkage or an unsubstituted methylene group,
R₂ and R₃ are each independently a direct linkage, —O—*, or a substituted or unsubstituted methylene group, and
n1 is an integer of 1 to 5.

12. The method for manufacturing a light emitting element of claim 11, wherein the composition is provided by an inkjet printing method or a dispensing method.

13. The method for manufacturing a light emitting element of claim 11, wherein
the composition further comprises a first solvent in which the metal nanoparticles are dispersed, and
the first solvent comprises a material represented by Formula S-1: 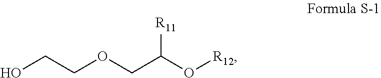
in Formula S-1,
R₁₁ and R₁₂ are each independently a hydrogen atom or a substituted or unsubstituted alkyl group of 1 to 10 carbon atoms, and/or combined with an adjacent group to provide a ring.

14. The method for manufacturing a light emitting element of claim 11, wherein
the composition further comprises a first solvent in which the metal nanoparticles are dispersed, and
the first solvent comprises a material represented by at least one selected from among S-11 to S-18:

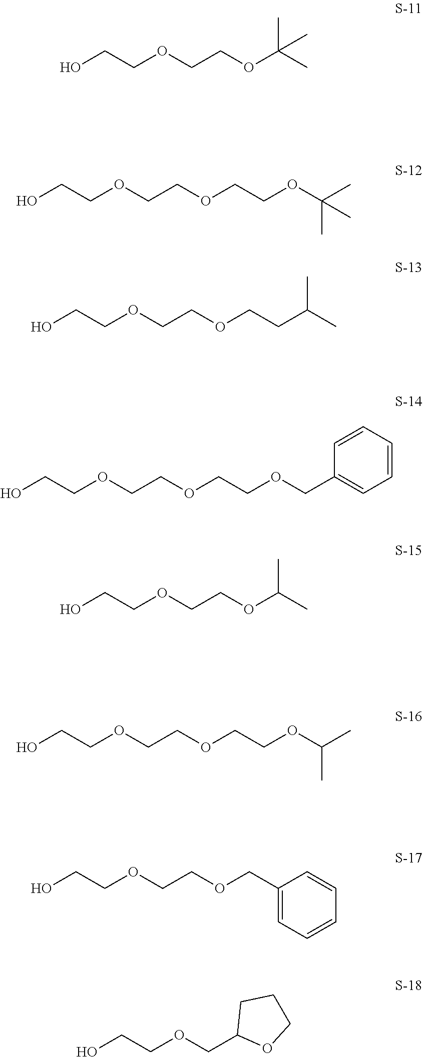

15. The method for manufacturing a light emitting element of claim 11, wherein
preparing the metal nanoparticles is prior to the providing of the composition, and
the preparing of the metal nanoparticles comprises:
preparing the core; and
providing the core with the ionic compound to prepare the metal nanoparticles in which the ligand is bonded to a surface of the core.

16. The method for manufacturing a light emitting element of claim 15, wherein
the preparing of the core comprises:
preparing a mixture comprising a zinc precursor, a magnesium precursor, a first precursor and a second solvent; and
providing the mixture with a third solvent comprising a hydroxyl group, and
the first precursor comprises a sodium precursor or a lithium precursor.

17. The method for manufacturing a light emitting element of claim 16, wherein each of the zinc precursor, the magnesium precursor, and the first precursor comprises an acetate ion or a halogen ion.

18. The method for manufacturing a light emitting element of claim 16, wherein the second solvent comprises at least one selected from among water (H₂O), ethylene glycol and dimethyl sulfoxide.

19. The method for manufacturing a light emitting element of claim 16, wherein the third solvent comprises at least one selected from among potassium hydroxide, sodium hydroxide, trimethylammonium hydroxide (TMAM), and tetramethylammonium hydroxide (TMAH).

20. The method for manufacturing a light emitting element of claim 11, wherein the metal oxide is represented by Formula M-1:
Znₓ₁Mg_{y1}Q_{z1}O, Formula M-1
in Formula M-1,
Q is Na or Li,
a sum of x1, y1 and z1 is 1,
x1 is a real number greater than 0 and at most 0.95,
y1 is a real number greater than 0 and at most 0.3, and
z1 is a real number greater than 0 and at most 0.3.

21. The method for manufacturing a light emitting element of claim 11, wherein
the ligand comprises a first ligand comprising a Na⁺ ion of Formula 1 and a second ligand comprising an O⁻ ion of Formula 1, and
each of the first ligand and the second ligand is bonded to a surface of the core.

22. The method for manufacturing a light emitting element of claim 21, wherein
the first ligand is bonded to oxygen (O) at the surface, and
the second ligand is bonded to at least one selected from among zinc (Zn) and magnesium (Mg) at the surface.

23. The method for manufacturing a light emitting element of claim 11, wherein
the providing of the emission layer is performed after the providing of the electron transport region, and
the providing of the at least one functional layer further comprises providing a hole transport region after the providing of the emission layer.

24. The method for manufacturing a light emitting element of claim 11, wherein
the providing of the emission layer is performed prior to the providing of the electron transport region, and
the providing of the at least one functional layer further comprises providing a hole transport region prior to the providing of the emission layer.

25. A display device comprising:
a circuit layer; and
a display element layer on the circuit layer and comprising a pixel definition layer in which a pixel opening part is defined and a light emitting element,
wherein
the light emitting element comprises:
a first electrode exposed via the pixel opening part;
a second electrode on the first electrode; and
at least one functional layer between the first electrode and the second electrode,
the at least one functional layer comprises an emission layer comprising quantum dots and an electron transport region comprising metal nanoparticles,
each of the metal nanoparticles comprises:
a core comprising a metal oxide composed of zinc (Zn), magnesium (Mg), oxygen (O) and a first component; and
a ligand bonded to the core and derived from an ionic compound represented by Formula 1, and
the first component comprises sodium (Na) or lithium (Li): 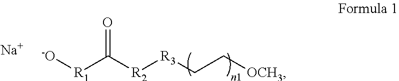
in Formula 1,
R₁ is a direct linkage or an unsubstituted methylene group,
R₂ and R₃ are each independently a direct linkage, —O—*, or a substituted or unsubstituted methylene group, and
n1 is an integer of 1 to 5.

26. The display device of claim 25, wherein the metal oxide is represented by Formula M-1:
Znₓ₁Mg_{y1}Q_{z1}O, Formula M-1
in Formula M-1,
Q is Na or Li,
a sum of x1, y1 and z1 is 1,
x1 is a real number greater than 0 and at most 0.95,
y1 is a real number greater than 0 and at most 0.3, and
z1 is a real number greater than 0 and at most 0.3.

27. The display device of claim 25, wherein
the ligand comprises a first ligand comprising a Na⁺ ion of Formula 1 and a second ligand comprising an O⁻ ion of Formula 1, and
each of the first ligand and the second ligand is bonded to a surface of the core.

28. The display device of claim 27, wherein
the first ligand is bonded to oxygen (O) at the surface, and
the second ligand is bonded to at least one selected from among zinc (Zn) and magnesium (Mg) at the surface.

29. The display device of claim 25, wherein
the emission layer is between the electron transport region and the second electrode, and
the at least one functional layer further comprises a hole transport region between the emission layer and the second electrode.

30. The display device of claim 25, wherein
the emission layer is between the first electrode and the electron transport region, and
the at least one functional layer further comprises a hole transport region between the first electrode and the emission layer.
